(19) United States
(12) Patent Application Publication
(10) Pub. No.: US 2025/0321263 A1
(43) Pub. Date: Oct. 16, 2025

(54) SENSOR DRIVER, ELECTRONIC DEVICE INCLUDING THE SAME, AND ELECTRONIC DEVICE TESTING METHOD

(71) Applicant: Samsung Display Co., LTD., Yongin-si (KR)

(72) Inventors: Hyunjee JEON, Yongin-si (KR); KYOWON KU, Yongin-si (KR); HYUNGBAE KIM, Yongin-si (KR); SANGHYUN LIM, Yongin-si (KR)

(21) Appl. No.: 19/000,334

(22) Filed: Dec. 23, 2024

(30) Foreign Application Priority Data
Apr. 15, 2024 (KR) 10-2024-0049900
Jul. 9, 2024 (KR) 10-2024-0090234

(51) Int. Cl. G01R 31/28

(52) U.S. Cl. CPC G01R 31/2829; G01R 31/2825; G01R 31/2884

(57) ABSTRACT

An electronic device testing method includes providing an electronic device including a sensor layer and a sensor driver, and testing the electronic device as the sensor driver transmits a test signal to the sensor layer. The sensor layer includes a plurality of first electrodes and a plurality of second electrodes. The sensor driver includes an in-phase filter and a quadrature phase filter. The testing of the electronic device includes testing the sensor driver. The testing of the sensor driver includes transmitting the test signal to the plurality of first electrodes and receiving a sensing signal through the plurality of second electrodes, outputting a first test value, outputting a second test value, and comparing the first test value and the second test value.

### CROSS-REFERENCE TO RELATED APPLICATIONS

The present application claims priority to and the benefit of Korean Patent Application No. 10-2024-0049900, filed on Apr. 15, 2024, and No. 10-2024-0090234 filed, on Jul. 9, 2024, in the Korean Intellectual Property Office, the entire disclosures of which are incorporated herein by reference.

### BACKGROUND

Aspects of some embodiments of the present disclosure described herein relate to a sensor driver capable of sensing an input by a pen, an electronic device including the same, and an electronic device testing method.

Each of multimedia electronic devices such as a TV, a mobile phone, a tablet personal computer (PC), a notebook computer, a navigation system, a game console, and the like includes a display device that displays images. In addition to a general input method such as a button, a keyboard, a mouse, or the like, the electronic devices may include a sensor layer (or an input sensor) capable of providing a touch-based input method that allows a user to enter information or commands relatively easily and intuitively. The sensor layer may sense a user's touch or pressure. In the meantime, there is an increasing demand for employing a pen for a fine touch input for a user who is accustomed to entering information by using writing instruments or for a specific application (e.g. an application for sketching or drawing).

The above information disclosed in this Background section is only for enhancement of understanding of the background and therefore the information discussed in this Background section does not necessarily constitute prior art.

### SUMMARY

Aspects of some embodiments of the present disclosure include a sensor driver capable of sensing an input by a pen, an electronic device including the same, and an electronic device testing method.

According to some embodiments, an electronic device testing method includes providing an electronic device including a sensor layer and a sensor driver driving the sensor layer, and testing the electronic device as the sensor driver transmits a test signal to the sensor layer. According to some embodiments, the sensor layer includes a plurality of first electrodes arranged in a first direction and extending in a second direction intersecting the first direction, and a plurality of second electrodes arranged in the second direction and extending in the first direction. According to some embodiments, the sensor driver includes an in-phase filter and a quadrature phase filter. According to some embodiments, the testing of the electronic device includes testing the sensor driver. According to some embodiments, the testing of the sensor driver includes transmitting the test signal to the plurality of first electrodes and receiving a sensing signal for the test signal through the plurality of second electrodes, outputting a first test value obtained as the sensing signal passes through the in-phase filter, outputting a second test value obtained as the sensing signal passes through the quadrature phase filter, and comparing the first test value and the second test value.

According to some embodiments, the comparing of the first test value and the second test value may include determining that the quadrature phase filter is operating normally, when the first test value and the second test value are within a normal range and are similar to each other, and determining that the quadrature phase filter is abnormal, when the first test value is within the normal range and the second test value is outside the normal range.

According to some embodiments, the receiving of the sensing signal may include measuring mutual capacitance between the plurality of first electrodes and the plurality of second electrodes.

According to some embodiments, the sensor driver may further include a current conveyor circuit. According to some embodiments, the testing of the sensor driver may further include receiving a third test value obtained as the sensing signal passes through the current conveyor circuit and the in-phase filter, and comparing the third test value and the second test value.

According to some embodiments, the comparing of the third test value and the second test value may include determining that the current conveyor circuit is abnormal, when the second test value is within the normal range and the third test value is outside the normal range.

According to some embodiments, the sensor layer further may include a plurality of first auxiliary electrodes arranged in the first direction, extending in the second direction, and overlapping the plurality of first electrodes, and a plurality of second auxiliary electrodes arranged in the second direction, extending in the first direction, and overlapping the plurality of second electrodes.

According to some embodiments, the testing of the electronic device may further include testing the sensor layer. According to some embodiments, the testing of the sensor layer may include testing a short state of the sensor layer, and testing an open state of the sensor layer.

According to some embodiments, the testing of the short state of the sensor layer may include transmitting the test signal to the plurality of first electrodes and receiving a 1-1st sensing signal for the test signal through the plurality of second electrodes, determining short states of the plurality of first electrodes and the plurality of second electrodes based on the 1-1st sensing signal, transmitting the test signal to the plurality of first auxiliary electrodes and receiving a 2-1st sensing signal for the test signal through the plurality of second auxiliary electrodes, and determining short states of the plurality of first auxiliary electrodes and the plurality of second auxiliary electrodes based on the 2-1st sensing signal.

According to some embodiments, the testing of the open state of the sensor layer may include transmitting the test signal to the plurality of first electrodes and receiving a 1-2nd sensing signal for the test signal through the plurality of second electrodes, determining open states of the plurality of first electrodes and the plurality of second electrodes based on the 1-2nd sensing signal, transmitting the test signal to the plurality of first auxiliary electrodes and receiving a 2-2nd sensing signal for the test signal through the plurality of second auxiliary electrodes, and determining open states of the plurality of first auxiliary electrodes and the plurality of second auxiliary electrodes based on the 2-2nd sensing signal.

According to some embodiments, the testing of the sensor layer may further include measuring sensitivity of a pen, and supplementarily testing the plurality of first auxiliary electrodes and the plurality of second auxiliary electrodes.

According to some embodiments, the measuring of the sensitivity of the pen may include transmitting the test signal to the plurality of first electrodes and receiving a third sensing signal for the test signal through the plurality of first auxiliary electrodes, transmitting the test signal to the plurality of second electrodes and receiving a fourth sensing signal for the test signal through the plurality of second auxiliary electrodes, and testing the sensitivity of the pen based on the third sensing signal and the fourth sensing signal.

According to some embodiments, the supplementarily testing of the plurality of first auxiliary electrodes and the plurality of second auxiliary electrodes may include transmitting the test signal to the plurality of first electrodes and receiving a fifth sensing signal for the test signal through the plurality of second auxiliary electrodes, and testing the plurality of second auxiliary electrodes based on the fifth sensing signal.

According to some embodiments, the supplementarily testing of the plurality of first auxiliary electrodes and the plurality of second auxiliary electrodes may further include transmitting the test signal to the plurality of second electrodes and receiving a sixth sensing signal for the test signal through the plurality of first auxiliary electrodes, and testing the plurality of first auxiliary electrodes based on the sixth sensing signal.

According to some embodiments, the testing of the plurality of second auxiliary electrodes may include determining that an open occurs in an area, which overlaps the another one of the plurality of first electrodes, in the plurality of second auxiliary electrodes when a test value of the fifth sensing signal for the test signal transmitted to one of the plurality of first electrodes is greater than a test value of the fifth sensing signal for the test signal transmitted to another one adjacent to the one of the plurality of first electrodes.

According to some embodiments, a sensor driver that drives a sensor layer including a plurality of first electrodes and a plurality of second electrodes respectively intersecting the plurality of first electrodes in an insulation method includes a driver that outputs a test signal to the sensor layer, a receiving unit electrically connected to the sensor layer, an in-phase filter electrically connected to the receiving unit, a quadrature phase filter electrically connected to the receiving unit, and an analysis unit electrically connected to the in-phase filter and the quadrature phase filter. The driver transmits the test signal to the plurality of first electrodes. According to some embodiments, the receiving unit receives a first sensing signal for the test signal from the plurality of second electrodes. According to some embodiments, the first sensing signal passes through the in-phase filter and is output as a first test value. The first sensing signal passes through the quadrature phase filter and is output as a second test value.

According to some embodiments, the first sensing signal may be mutual capacitance between the plurality of first electrodes and the plurality of second electrodes. According to some embodiments, the analysis unit may test the quadrature phase filter by comparing the first test value and the second test value.

According to some embodiments, the sensor driver may further include a filter unit connected to the receiving unit, and an analog-to-digital converter connected between the analysis unit and the in-phase filter or the quadrature phase filter.

According to some embodiments, the sensor layer may further include a plurality of first auxiliary electrodes arranged in a first direction, extending in a second direction intersecting the first direction, and overlapping the plurality of first electrodes, and a plurality of second auxiliary electrodes arranged in the second direction, extending in the first direction, and overlapping the plurality of second electrodes. According to some embodiments, the driver may transmit the test signal to the plurality of first auxiliary electrodes, and the receiving unit may output a second sensing signal through the plurality of second auxiliary electrodes.

According to some embodiments, the driver may transmit the test signal to the plurality of first electrodes, and the receiving unit may output a third sensing signal through the plurality of first auxiliary electrodes. According to some embodiments, the driver may transmit the test signal to the plurality of second electrodes, and the receiving unit may output a fourth sensing signal through the plurality of second auxiliary electrodes.

According to some embodiments, the driver may transmit the test signal to the plurality of first electrodes and may output a fifth sensing signal for the test signal through the plurality of first auxiliary electrodes. According to some embodiments, the driver may transmit the test signal to the plurality of second electrodes and may output a sixth sensing signal for the test signal through the plurality of second auxiliary electrodes.

According to some embodiments, an electronic device includes a display layer, a sensor layer on the display layer, and a sensor driver that drives the sensor layer. According to some embodiments, the sensor layer includes a plurality of first electrodes arranged in a first direction and extending in a second direction intersecting the first direction, and a plurality of second electrodes arranged in the second direction and extending in the first direction. According to some embodiments, the sensor driver includes a driver that outputs a test signal to the sensor layer, a receiving unit electrically connected to the sensor layer, an in-phase filter electrically connected to the receiving unit, and a quadrature phase filter electrically connected to the receiving unit. According to some embodiments, the driver transmits the test signal to the plurality of first electrodes. According to some embodiments, the receiving unit receives a sensing signal for the test signal from the plurality of second electrodes. According to some embodiments, the sensing signal passes through the in-phase filter and is output as a first test value, and the sensing signal passes through the quadrature phase filter and is output as a second test value.

According to some embodiments, the first sensing signal may be mutual capacitance between the plurality of first electrodes and the plurality of second electrodes.

According to some embodiments, the sensor layer may further include a plurality of first auxiliary electrodes arranged in the first direction, extending in the second direction, and overlapping the plurality of first electrodes, and a plurality of second auxiliary electrodes arranged in the second direction, extending in the first direction, and overlapping the plurality of second electrodes. According to some embodiments, the driver may transmit the test signal to the plurality of first auxiliary electrodes, and the receiving unit may output a second sensing signal through the plurality of second auxiliary electrodes.

According to some embodiments, the driver may transmit the test signal to the plurality of first electrodes, and the receiving unit may output a third sensing signal through the plurality of first auxiliary electrodes. According to some embodiments, the driver may transmit the test signal to the plurality of second electrodes, and the receiving unit may output a fourth sensing signal through the plurality of second auxiliary electrodes.

According to some embodiments, the driver may transmit the test signal to the plurality of first electrodes and may output a fifth sensing signal for the test signal through the plurality of first auxiliary electrodes. According to some embodiments, the driver may transmit the test signal to the plurality of second electrodes and may output a sixth sensing signal for the test signal through the plurality of second auxiliary electrodes.

According to some embodiments, the sensor driver may further include a filter unit connected to the receiving unit, and an analog-to-digital converter electrically connected to the in-phase filter and the quadrature phase filter.

According to some embodiments, the sensor driver may further include a current conveyor circuit electrically connected to the in-phase filter.

### BRIEF DESCRIPTION OF THE FIGURES

The above and other aspects and features of the present disclosure will become apparent by describing in detail embodiments thereof with reference to the accompanying drawings.

FIG. 1A is a perspective view of an electronic device, according to some embodiments of the present disclosure.

FIG. 1B is a rear perspective view of an electronic device, according to some embodiments of the present disclosure.

FIG. 2 is a perspective view of an electronic device, according to some embodiments of the present disclosure.

FIG. 3 is a perspective view of an electronic device, according to some embodiments of the present disclosure.

FIG. 4 is a schematic cross-sectional view of a display panel, according to some embodiments of the present disclosure.

FIG. 5 is a block diagram for describing an operation of an electronic device, according to some embodiments of the present disclosure.

FIG. 6 is a cross-sectional view of a display panel, according to some embodiments of the present disclosure.

FIG. 7 is a cross-sectional view of a sensor layer, according to some embodiments of the present disclosure.

FIG. 8 is a plan view of a sensor layer, according to some embodiments of the present disclosure.

FIG. 9 is an enlarged plan view of one sensing unit, according to some embodiments of the present disclosure.

FIG. 10A is a plan view showing a first conductive layer of a sensing unit, according to some embodiments of the present disclosure.

FIG. 10B is a plan view showing a second conductive layer of a sensing unit, according to some embodiments of the present disclosure.

FIG. 10C is a cross-sectional view of a sensor layer taken along the line I-I′ illustrated in FIGS. 10A and 10B, according to some embodiments of the present disclosure.

FIG. 11A is a plan view showing a first conductive layer of a sensing unit, according to some embodiments of the present disclosure.

FIG. 11B is a plan view showing a second conductive layer of a sensing unit, according to some embodiments of the present disclosure.

FIG. 11C is a cross-sectional view of a sensor layer taken along the line II-II′ illustrated in FIGS. 11A and 11B, according to some embodiments of the present disclosure.

FIG. 12A is an enlarged plan view of area AA′ shown in FIG. 10A, according to some embodiments of the present disclosure.

FIG. 12B is an enlarged plan view of area BB′ shown in FIG. 10B, according to some embodiments of the present disclosure.

FIG. 13 is a view illustrating an operation of a sensor driver, according to some embodiments of the present disclosure.

FIG. 14 is a view illustrating an operation of a sensor driver, according to some embodiments of the present disclosure.

FIGS. 15A and 15B are views for describing a first mode, according to some embodiments of the present disclosure.

FIG. 16 is a diagram for describing a first mode, according to some embodiments of the present disclosure.

FIG. 17A is a diagram for describing a second mode, according to some embodiments of the present disclosure.

FIG. 17B are graphs illustrating waveforms of a first signal and a second signal, according to some embodiments of the present disclosure.

FIG. 18A is a diagram for describing a second mode, according to some embodiments of the present disclosure.

FIG. 18B is a diagram for describing a second mode based on a sensing unit, according to some embodiments of the present disclosure.

FIG. 19 is a flowchart illustrating an electronic device testing method, according to some embodiments of the present disclosure.

FIG. 20 is a block diagram illustrating a sensor driver, according to some embodiments of the present disclosure.

FIG. 21 is a flowchart illustrating a method for testing a sensor driver, according to some embodiments of the present disclosure.

FIG. 22 is a diagram schematically illustrating a sensor layer and a sensor driver, according to some embodiments of the present disclosure.

FIG. 23 is a flowchart illustrating a method for testing a sensor layer, according to some embodiments of the present disclosure.

FIGS. 24 and 25 are diagrams schematically illustrating a sensor layer and a sensor driver, according to some embodiments of the present disclosure.

FIG. 26A is a drawing for describing a connection relationship between a plurality of fourth electrodes and a sensor driver, according to some embodiments of the present disclosure.

FIG. 26B is a drawing for describing a connection relationship between a plurality of fourth electrodes and a sensor driver, according to some embodiments of the present disclosure.

FIG. 27A is a diagram schematically illustrating one channel, according to some embodiments of the present disclosure.

FIG. 27B is a diagram schematically illustrating one channel, according to some embodiments of the present disclosure.

FIG. 28 is a diagram schematically illustrating a sensor layer and a sensor driver, according to some embodiments of the present disclosure.

FIG. 29 is a diagram schematically illustrating a sensor layer and a sensor driver, according to some embodiments of the present disclosure.

FIG. 30 is a diagram schematically illustrating a sensor layer and a sensor driver, according to some embodiments of the present disclosure.

FIG. 31 is a diagram illustrating a sensor layer, in which an open occurs in a second auxiliary electrode, according to some embodiments of the present disclosure.

FIG. 32 is a diagram schematically illustrating a sensor layer and a sensor driver, according to some embodiments of the present disclosure.

FIG. 33 is a block diagram illustrating a sensor driver, according to some embodiments of the present disclosure.

### DETAILED DESCRIPTION

In the specification, the expression that a first component (or region, layer, part, portion, etc.) is “on”, “connected with”, or “coupled with” a second component means that the first component is directly on, connected with, or coupled with the second component or means that a third component is interposed therebetween.

The same reference numerals refer to the same components. Also, in drawings, the thickness, ratio, and dimension of components are exaggerated for effectiveness of description of technical contents. The term “and/or” includes one or more combinations in each of which associated elements are defined.

Although the terms “first”, “second”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The articles “a,” “an,” and “the” are singular in that they have a single referent, but the use of the singular form in the specification should not preclude the presence of more than one referent.

Also, the terms “under”, “below”, “on”, “above”, etc. are used to describe the correlation of components illustrated in drawings. The terms that are relative in concept are described based on a direction shown in drawings.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Terms “part” and “unit” mean a software component or a hardware component that performs a specific function. For example, the hardware component may include a field-programmable gate array (FPGA) or an application-specific integrated circuit (ASIC). The software component may refer to executable codes and/or data used by the executable codes in an addressable storage medium. Accordingly, the software components may be, for example, object-oriented software components, class components, and task components, and may include processes, functions, attributes, procedures, subroutines, program code segments, drivers, firmware, microcodes, circuits, data, databases, data structures, tables, arrays, or variables.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, aspects of some embodiments of the present disclosure will be described with reference to accompanying drawings.

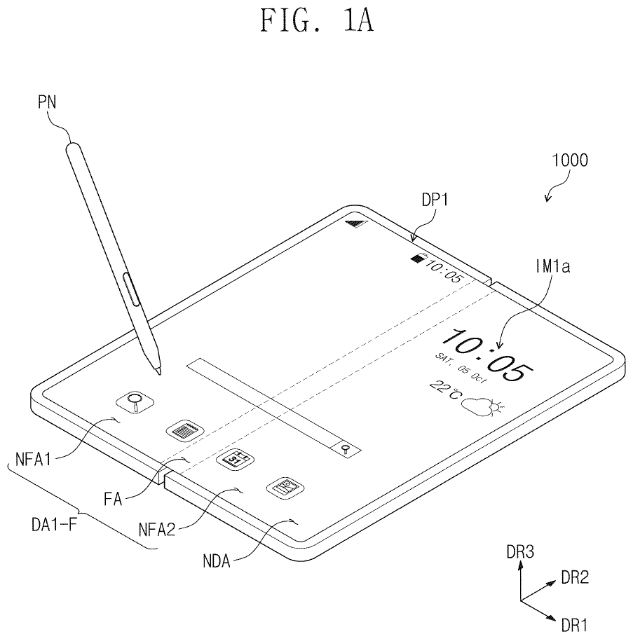

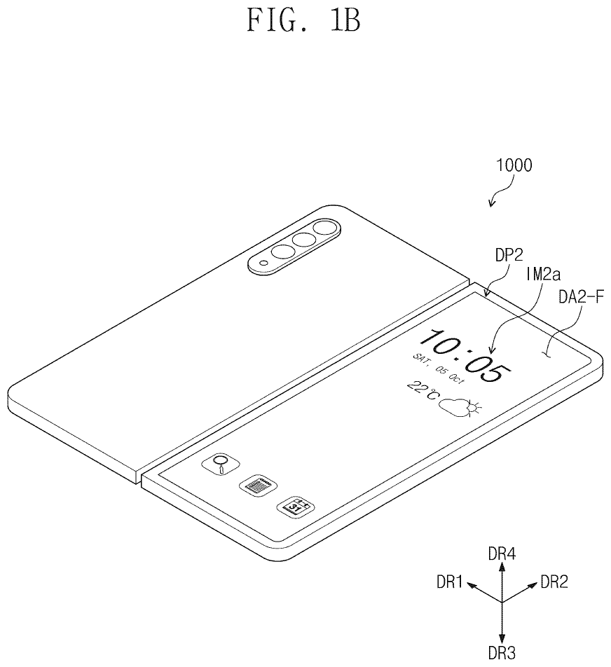

FIG. 1A is a perspective view of an electronic device, according to some embodiments of the present disclosure. FIG. 1B is a rear perspective view of an electronic device, according to some embodiments of the present disclosure.

Referring to FIGS. 1A and 1B, an electronic device 1000 may be a device activated depending on an electrical signal. For example, the electronic device 1000 may display an image and may sense inputs applied from the outside. The external input may be a user input. The user input may include various types of external inputs such as a part of the body of a user, a pen PN, light, heat, or pressure.

The electronic device 1000 may include a first display panel DP1 and a second display panel DP2. The first display panel DP1 and the second display panel DP2 may be panels separate from each other. The first display panel DP1 may be referred to as a “main display panel”. The second display panel DP2 may be referred to as an “auxiliary display panel” or “external display panel”.

The first display panel DP1 may include a first display unit DA1-F. The second display panel DP2 may include a second display unit DA2-F. An area of the second display panel DP2 may be smaller than an area of the first display panel DP1. The area of the first display unit DA1-F may be greater than the area of the second display unit DA2-F so as to correspond to the size of the first display panel DP1 and the size of the second display panel DP2.

While the electronic device 1000 is unfolded, the first display unit DA1-F may have a plane parallel (or substantially parallel) to a first direction DR1 and a second direction DR2. A thickness direction of the electronic device 1000 may be parallel to a third direction DR3 intersecting the first direction DR1 and the second direction DR2. Accordingly, front surfaces (or upper surfaces) and back surfaces (or lower surfaces) of members constituting the electronic device 1000 may be defined based on the third direction DR3.

The first display panel DP1 or the first display unit DA1-F may include a folding area FA, which is folded and unfolded, and a plurality of non-folding areas NFA1 and NFA2 spaced from each other with the folding area FA therebetween. The second display panel DP2 may overlap one of the plurality of non-folding areas NFA1 and NFA2. For example, the second display panel DP2 may overlap the first non-folding area NFA1.

A display direction of a first image IM1a displayed in a part (e.g., the first non-folding area NFA1) of the first display panel DP1 may be opposite to a display direction of a second image IM2a displayed in the second display panel DP2. For example, the first image IM1a may be displayed in the third direction DR3, and the second image IM2a may be displayed in a fourth direction DR4, which is the opposite direction to the third direction DR3.

According to some embodiments of the present disclosure, the folding area FA may be bent based on a folding axis extending in a direction (e.g., the second direction DR2) parallel to a long side of the electronic device 1000 without damaging the electronic device 1000. While the electronic device 1000 is folded, the folding area FA has a curvature (e.g., a set or predetermined curvature) and radius of curvature. The first non-folding area NFA1 and the second non-folding area NFA2 may face each other, and the electronic device 1000 may be inner-folded such that the first display unit DA1-F is not exposed to the outside.

According to some embodiments of the present disclosure, the electronic device 1000 may be outer-folded such that the first display unit DA1-F is exposed to the outside. According to some embodiments of the present disclosure, the electronic device 1000 may be capable of both in-folding and out-folding in an unfolded state, but is not limited thereto.

FIG. 1A illustrates that one folding area FA is defined in the electronic device 1000, but embodiments according to the present disclosure are not limited thereto. For example, a plurality of folding axes and a plurality of folding areas corresponding thereto are defined in the electronic device 1000. The electronic device 1000 may be in-folded or out-folded in a state where each of the plurality of folding areas is unfolded.

According to some embodiments of the present disclosure, at least one of the first display panel DP1 and the second display panel DP2 may sense an input by the pen PN even when it does not include a digitizer. Accordingly, because the digitizer for sensing the pen PN is omitted, an increase in the thickness of the electronic device 1000, an increase in the weight of the electronic device 1000, or a decrease in flexibility of the electronic device 1000 may not occur due to the addition of a digitizer. Accordingly, not only the first display panel DP1 but also the second display panel DP2 may be designed to sense the pen PN.

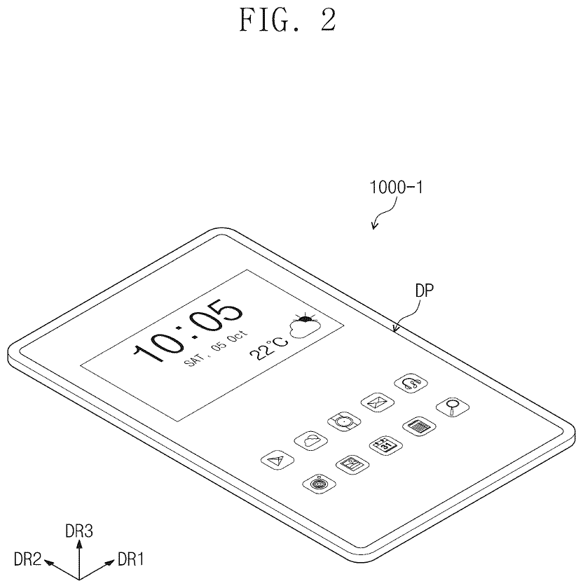

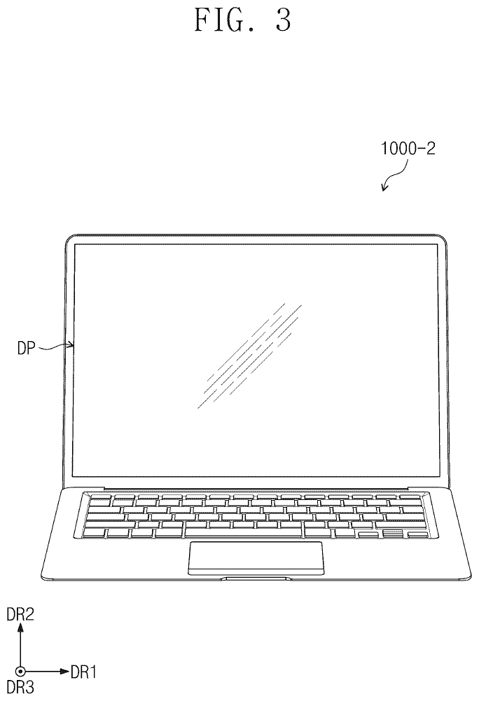

FIG. 2 is a perspective view of an electronic device, according to some embodiments of the present disclosure. FIG. 3 is a perspective view of an electronic device, according to some embodiments of the present disclosure.

FIG. 2 shows that an electronic device 1000-1 is a mobile phone, and the electronic device 1000-1 may include a display panel DP. FIG. 3 shows that an electronic device 1000-2 is a notebook PC, and the electronic device 1000-2 may include a display panel DP.

According to some embodiments of the present disclosure, the display panel DP may sense inputs applied from the outside. The external input may be a user input. The user input may include various types of external inputs such as a part of the body of a user, the pen PN (see FIG. 1A), light, heat, or pressure.

According to some embodiments of the present disclosure, the display panel DP may sense an input by the pen PN (see FIG. 1A) even though the display panel DP does not include a digitizer. Accordingly, because the digitizer for sensing the pen PN is omitted, the thickness and weight of the electronic device 1000-1 or 1000-2 may not increase due to the addition of a digitizer.

FIG. 1A shows a foldable type of the electronic device 1000, and FIG. 2 shows a bar type of the electronic device 1000-1. However, embodiments according to the present disclosure as described below are not limited thereto. For example, the descriptions described below may be applied to various electronic devices, such as a rollable type of an electronic device, a slideable type of an electronic device, and a stretchable type of an electronic device.

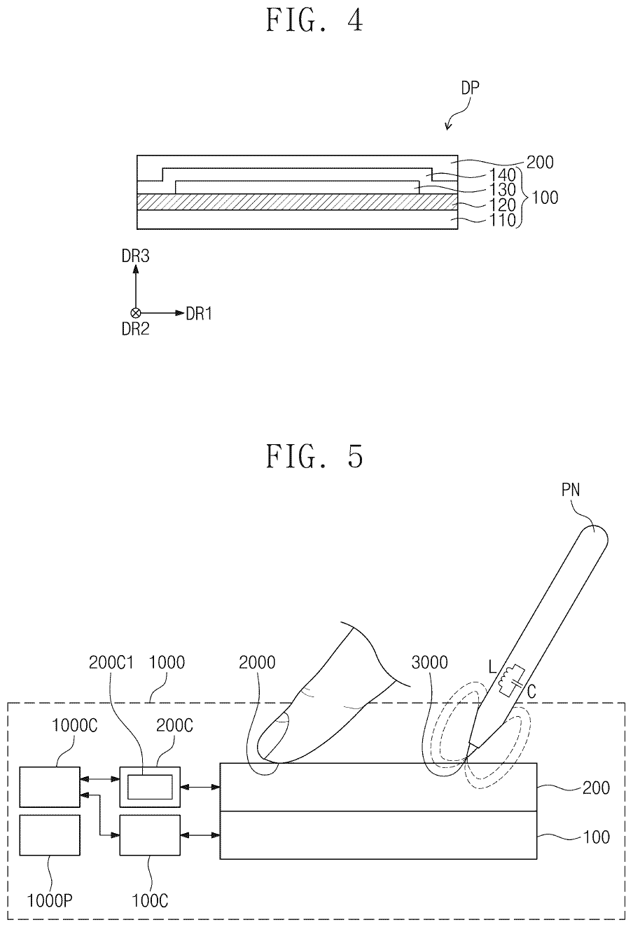

FIG. 4 is a schematic cross-sectional view of a display panel, according to some embodiments of the present disclosure.

Referring to FIG. 4, the display panel DP may include a display layer 100 and a sensor layer 200.

The display layer 100 may include a base layer 110, a circuit layer 120, a light emitting element layer 130, and an encapsulation layer 140.

The base layer 110 may be a member that provides a base surface on which the circuit layer 120 is located. The base layer 110 may include a multi-layer structure or a single-layer structure. The base layer 110 may be a glass substrate, a metal substrate, a silicon substrate, or a polymer substrate, but is not particularly limited thereto.

The circuit layer 120 may be located on the base layer 110. The circuit layer 120 may include an insulating layer, a semiconductor pattern, a conductive pattern, and a signal line. The insulating layer, the semiconductor layer, and the conductive layer may be formed on the base layer 110 in a manner such as coating, evaporation, or the like. The insulating layer, the semiconductor layer, and the conductive layer may be selectively patterned by performing a photolithography process multiple times.

The light emitting element layer 130 may be located on the circuit layer 120. The light emitting element layer 130 may include a light emitting element. For example, the light emitting element layer 130 may include an organic luminescent material, an inorganic luminescent material, an organic-inorganic luminescent material, a quantum dot, a quantum rod, a micro-LED, or a nano-LED.

The encapsulation layer 140 may be located on the light emitting element layer 130. The encapsulation layer 140 may protect the light emitting element layer 130 from foreign substances such as moisture, oxygen, and dust particles.

The sensor layer 200 may be located on the display layer 100. The sensor layer 200 may sense an external input applied from the outside. The sensor layer 200 may be an integrated sensor formed continuously during the manufacturing process of the display layer 100, or may be an external sensor attached to the display layer 100. The sensor layer 200 may be referred to as a “sensor”, an “input sensing layer”, an “input sensing panel”, or an “electronic device for sensing input coordinates”.

According to some embodiments of the present disclosure, the sensor layer 200 may sense both inputs from a passive-type input means such as the user's body and an input device PN (see FIG. 1A) for generating a magnetic field of a resonant frequency (e.g., a set or predetermined resonant frequency).

FIG. 5 is a block diagram for describing an operation of an electronic device, according to some embodiments of the present disclosure.

Referring to FIG. 5, the electronic device 1000 may include the display layer 100, the sensor layer 200, a display driver 100C, a sensor driver 200C, a main driver 1000C, and a power supply circuit 1000P.

The sensor layer 200 may sense a first input 2000 or a second input 3000 applied from the outside. Each of the first input 2000 and the second input 3000 may be an input means capable of providing a change in the capacitance of the sensor layer 200 or an input means capable of causing an induced current in the sensor layer 200. For example, the first input 2000 may be a passive type of an input method such as a user's body. The second input 3000 may be an input by the pen PN or an input by an RFIC tag. For example, the pen PN may be a passive-type pen or an active-type pen.

According to some embodiments of the present disclosure, the pen PN may be a device that generates a magnetic field of a resonant frequency (e.g., a set or predetermined resonant frequency). The pen PN may be configured to transmit an output signal based on an electromagnetic resonance method. The pen PN may be referred to as an “input device”, an “input pen”, a “magnetic pen”, a “stylus pen”, or an “electromagnetic resonance pen”.

The pen PN may include an RLC resonant circuit, and the RLC resonant circuit may include an inductor L and a capacitor C. According to some embodiments of the present disclosure, the RLC resonant circuit may be a variable resonant circuit that varies a resonance frequency. In this case, the inductor L may be a variable inductor and/or the capacitor C may be a variable capacitor. However, embodiments according to the present disclosure are not particularly limited thereto.

The inductor L generates a current by a magnetic field formed in the sensor layer 200. However, embodiments according to the present disclosure are not particularly limited thereto. For example, when the pen PN operates in an active type or active mode, the pen PN may generate a current even when the pen PN does not receive a magnetic field from the outside. The generated current is delivered to the capacitor C. The capacitor C charges the current input from the inductor L, and discharges the charged current to the inductor L. Afterwards, the inductor L may emit a magnetic field at the resonant frequency. An induced current may flow in the sensor layer 200 by the magnetic field emitted by the pen PN, and the induced current may be delivered to the sensor driver 200C as a reception signal (or a sensing signal).

The main driver 1000C may control overall operations of the electronic device 1000. For example, the main driver 1000C may control operations of the display driver 100C and the sensor driver 200C. The main driver 1000C may include at least one microprocessor and may further include a graphics controller. The main driver 1000C may be referred to as an “application processor”, “central processing unit”, or “main processor”.

The display driver 100C may drive the display layer 100. The display driver 100C may receive image data and a control signal from the main driver 1000C. The control signal may include various signals. For example, the control signal may include an input vertical synchronization signal, an input horizontal synchronization signal, a main clock, and a data enable signal.

The sensor driver 200C may drive the sensor layer 200. The sensor driver 200C may receive a control signal from the main driver 1000C. The control signal may include a clock signal of the sensor driver 200C. Moreover, the control signal may further include a mode determination signal for determining operating modes of the sensor driver 200C and the sensor layer 200.

The sensor driver 200C may include an analysis unit 200C1. The sensor driver 200C may operate in a test mode. In the test mode, the sensor driver 200C may test the sensor driver 200C and the sensor layer 200 and may transmit the test result as sensing data to the analysis unit 200C1. The analysis unit 200C1 may analyze the sensing data and may store the analyzed result in a memory of the sensor driver 200C.

Moreover, the analysis unit 200C1 may transmit the result to the main driver 1000C. The main driver 1000C may transmit the result to the outside by using a communication system.

The sensor driver 200C may be implemented as an integrated circuit (IC) and may be electrically connected to the sensor layer 200. For example, the sensor driver 200C may be mounted directly on an area (e.g., a set or predetermined area) of the display panel or mounted on a separate printed circuit board in a chip-on-film (COF) method to be electrically connected to the sensor layer 200.

The sensor driver 200C and the sensor layer 200 may selectively operate in a first mode or a second mode. For example, the first mode may be a mode in which a touch input, for example, the first input 2000 is sensed. The second mode may be a mode in which an input of the pen PN, for example, the second input 3000 is sensed. The first mode may be referred to as a “touch sensing mode”, and the second mode may be referred to as a “pen sensing mode”.

The switching between the first mode and the second mode may be accomplished in a variety of manners. For example, the sensor driver 200C and the sensor layer 200 may be driven in a time-division method in the first mode and the second mode and may sense the first input 2000 and the second input 3000. Alternatively, the switching between the first mode and the second mode may occur due to a user's selection or the user's specific action, either the first mode or the second mode may be activated or deactivated by activating or deactivating a specific application, or one mode may be switched to the other mode. Alternatively, while operating alternately in the first mode and the second mode, the sensor driver 200C and the sensor layer 200 may be maintained in the first mode when the first input 2000 is sensed, or may be maintained in the second mode when the second input 3000 is sensed.

The sensor driver 200C may calculate coordinate information of an input based on a signal received from the sensor layer 200 and may provide the main driver 1000C with a coordinate signal having the coordinate information. The main driver 1000C executes an operation corresponding to a user input based on the coordinate signal. For example, the main driver 1000C may operate the display driver 100C such that a new application image is displayed on the display layer 100.

The power supply circuit 1000P may include a power management integrated circuit (PMIC). The power supply circuit 1000P may generate a plurality of driving voltages for driving the display layer 100, the sensor layer 200, the display driver 100C, and the sensor driver 200C. For example, the plurality of driving voltages may include a gate high voltage, a gate low voltage, a first driving voltage (e.g., ELVSS voltage), a second driving voltage (e.g., ELVDD voltage), an initialization voltage, and the like, but are not particularly limited to the example.

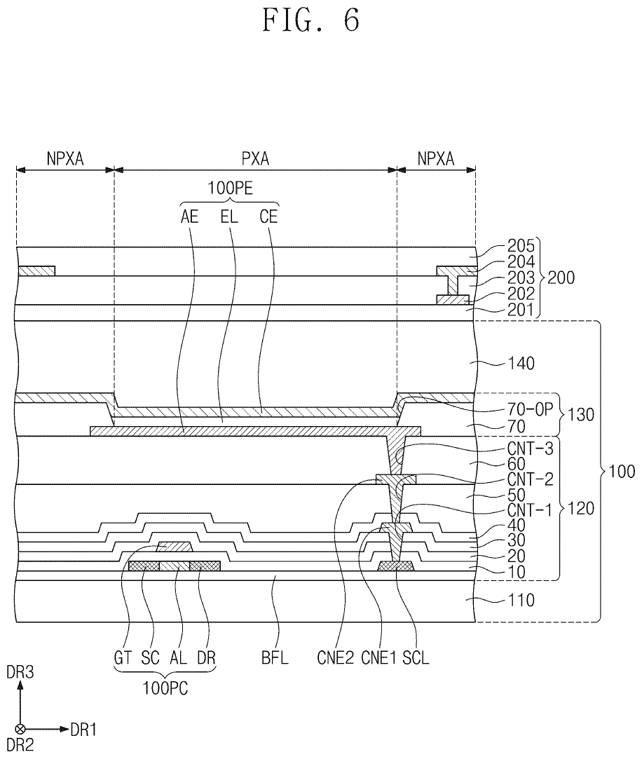

FIG. 6 is a cross-sectional view of a display panel, according to some embodiments of the present disclosure. In the description of FIG. 6, the same reference numerals are assigned to the same components described with reference to FIG. 4, and thus the descriptions thereof are omitted.

Referring to FIG. 6, at least one buffer layer BFL is formed on an upper surface of the base layer 110. The buffer layer BFL may relatively improve a bonding force between the base layer 110 and a semiconductor pattern. The buffer layer BFL may be formed of multiple layers. Alternatively, the display layer 100 may further include a barrier layer. The buffer layer BFL may include at least one of silicon oxide, silicon nitride, and silicon oxynitride. For example, the buffer layer BFL may include a structure in which a silicon oxide layer and a silicon nitride layer are stacked alternately.

Semiconductor patterns SC, AL, DR, and SCL may be located on the buffer layer BFL. The semiconductor patterns SC, AL, DR, and SCL may include polysilicon. However, embodiments according to the present disclosure are not limited thereto. For example, the semiconductor patterns SC, AL, DR, and SCL may include amorphous silicon, low-temperature polycrystalline silicon, or an oxide semiconductor.

FIG. 6 only illustrates a part of the semiconductor patterns SC, AL, DR, and SCL, and the semiconductor pattern may be further located in another area. The semiconductor patterns SC, AL, DR, and SCL may be arranged across pixels in a specific rule. The semiconductor patterns SC, AL, DR, and SCL may have a different electrical property depending on whether the semiconductor patterns SC, AL, DR, and SCL are doped. The semiconductor patterns SC, AL, DR, and SCL may include the first areas SC, DR, and SCL having a high conductivity, and the second area AL having a low conductivity. The first areas SC, DR, and SCL may be doped with an N-type dopant or a P-type dopant. A P-type transistor may include an area doped with the P-type dopant, and an N-type transistor may include an area doped with the N-type dopant. The second area AL may be an undoped area or an area doped with a concentration lower than a concentration in the first area.

A conductivity of each of the first areas SC, DR, and SCL is greater than a conductivity of the second area AL. The first areas SC, DR, and SCL may serve as an electrode or a signal line. The second area AL may correspond (or substantially correspond) to the active area AL (or a channel) of a transistor 100PC. In other words, a portion AL of the semiconductor patterns SC, AL, DR, and SCL may be the active area AL of the transistor 100PC; other parts SC and DR may be the source area SC or the drain area DR of the transistor 100PC; and the other part SCL may be a connection electrode or a connection signal line SCL.

Each of the pixels may have an equivalent circuit including seven transistors, one capacitor, and a light emitting element. The equivalent circuit diagram of a pixel may be modified in various shapes. The one transistor 100PC and one light emitting element 100PE included in a pixel are illustrated in FIG. 6 by way of example.

The source area SC, the active area AL, and the drain area DR of the transistor 100PC may be formed from the semiconductor patterns SC, AL, DR, and SCL. The source area SC and the drain area DR may extend in directions opposite to each other from the active area AL in a cross-sectional view. A portion of the connection signal line SCL formed from the semiconductor patterns SC, AL, DR, and SCL is illustrated in FIG. 6. According to some embodiments, the connection signal line SCL may be connected to the drain area DR of the transistor 100PC in a plan view.

A first insulating layer 10 may be located on the buffer layer BFL. The first insulating layer 10 may overlap a plurality of pixels in common and may cover the semiconductor patterns SC, AL, DR, and SCL. The first insulating layer 10 may be an inorganic layer and/or an organic layer, and may have a single-layer or multi-layer structure. The first insulating layer 10 may include at least one of aluminum oxide, titanium oxide, silicon oxide, silicon nitride, silicon oxynitride, zirconium oxide, and hafnium oxide. According to some embodiments, the first insulating layer 10 may be a silicon oxide layer having a single-layer structure. Not only the first insulating layer 10 but also an insulating layer of the circuit layer 120 to be described later may be an inorganic layer and/or an organic layer, and may have a single-layer structure or a multi-layer structure. The inorganic layer may include at least one of the above-described materials, but is not limited thereto.

A gate GT of the transistor 100PC is located on the first insulating layer 10. The gate GT may be a part of a metal pattern. The gate GT overlaps the active area AL. The gate GT may function as a mask in a process of reducing the semiconductor patterns SC, AL, DR, and SCL.

A second insulating layer 20 is located on the first insulating layer 10 and may cover the gate GT. The second insulating layer 20 may overlap pixels in common. The second insulating layer 20 may be an inorganic layer and/or an organic layer, and may have a single-layer structure or a multi-layer structure. The second insulating layer 20 may include at least one of silicon oxide, silicon nitride, and silicon oxynitride. According to some embodiments, the second insulating layer 20 may have a multi-layer structure including a silicon oxide layer and a silicon nitride layer.

A third insulating layer 30 may be located on the second insulating layer 20. The third insulating layer 30 may have a single-layer structure or a multi-layer structure. For example, the third insulating layer 30 may have a multi-layer structure including a silicon oxide layer and a silicon nitride layer.

A first connection electrode CNE1 may be located on the third insulating layer 30. The first connection electrode CNE1 may be connected to the connection signal line SCL through a contact hole CNT-1 penetrating the first, second, and third insulating layers 10, 20, and 30.

A fourth insulating layer 40 may be located on the third insulating layer 30. The fourth insulating layer 40 may be a single silicon oxide layer. A fifth insulating layer 50 may be located on the fourth insulating layer 40. The fifth insulating layer 50 may be an organic layer.

A second connection electrode CNE2 may be located on the fifth insulating layer 50. The second connection electrode CNE2 may be connected to the first connection electrode CNE1 through a contact hole CNT-2 penetrating the fourth insulating layer 40 and the fifth insulating layer 50.

A sixth insulating layer 60 may be located on the fifth insulating layer 50 and may cover the second connection electrode CNE2. The sixth insulating layer 60 may be an organic layer.

The light emitting element layer 130 may be located on the circuit layer 120. The light emitting element layer 130 may include the light emitting element 100PE. For example, the light emitting element layer 130 may include an organic luminescent material, an inorganic luminescent material, an organic-inorganic luminescent material, a quantum dot, a quantum rod, a micro-LED, or a nano-LED. Hereinafter, the description will be given under the condition that the light emitting element 100PE is an organic light emitting element, but embodiments according to the present disclosure are not particularly limited thereto.

The light emitting element 100PE may include a first electrode AE, a light emitting layer EL, and a second electrode CE.

The first electrode AE may be located on the sixth insulating layer 60. The first electrode AE may be connected to the second connection electrode CNE2 through a contact hole CNT-3 penetrating the sixth insulating layer 60.

A pixel defining layer 70 may be located on the sixth insulating layer 60 and may cover a portion of the first electrode AE. An opening 70-OP is defined in the pixel defining layer 70. The opening 70-OP of the pixel defining layer 70 exposes at least part of the first electrode AE.

The first display unit DA1-F (see FIG. 1A) may include an emission area PXA and a non-emission area NPXA adjacent to the emission area PXA. The non-emission area NPXA may surround the emission area PXA. According to some embodiments, the emission area PXA is defined to correspond to a partial area of the first electrode AE, which is exposed by the opening 70-OP.

The light emitting layer EL may be located on the first electrode AE. The light emitting layer EL may be located in an area corresponding to the opening 70-OP. That is, the light emitting layer EL may be separately formed on each of pixels. When the light emitting layers EL are separately formed in each of pixels, each of the light emitting layers EL may emit light of at least one of a blue color, a red color, and a green color. However, embodiments according to the present disclosure are not limited thereto. For example, the light emitting layer EL may be connected and included in each of the pixels in common. In this case, the light emitting layer EL may provide blue light or white light.

The second electrode CE may be located on the light emitting layer EL. The second electrode CE may be included in a plurality of pixels in common while having an integral shape.

According to some embodiments of the present disclosure, a hole control layer may be interposed between the first electrode AE and the light emitting layer EL. The hole control layer may be located in common in the emission area PXA and the non-emission area NPXA. The hole control layer may include a hole transport layer and may further include a hole injection layer. An electron control layer may be interposed between the light emitting layer EL and the second electrode CE. The electron control layer may include an electron transport layer, and may further include an electron injection layer. The hole control layer and the electron control layer may be formed in common in a plurality of pixels by using an open mask or inkjet process.

The encapsulation layer 140 may be arranged on the light emitting element layer 130. The encapsulation layer 140 may include an inorganic layer, an organic layer, and an inorganic layer sequentially stacked, and layers constituting the encapsulation layer 140 are not limited thereto. The inorganic layers may protect the light emitting element layer 130 from moisture and oxygen, and the organic layer may protect the light emitting element layer 130 from a foreign material such as dust particles. The inorganic layers may include a silicon nitride layer, a silicon oxynitride layer, a silicon oxide layer, a titanium oxide layer, an aluminum oxide layer, or the like. The organic layer may include, but is not limited to, an acrylic-based organic layer.

The sensor layer 200 may include a base layer 201, a first conductive layer 202, a sensing insulating layer 203, a second conductive layer 204, and a cover insulating layer 205.

The base layer 201 may be an inorganic layer including at least one of silicon nitride, silicon oxynitride, and silicon oxide. Alternatively, the base layer 201 may be an organic layer including an epoxy resin, an acrylate resin, or an imide-based resin. The base layer 201 may have a single-layer structure or may have a multi-layer structure stacked in the third direction DR3.

Each of the first conductive layer 202 and the second conductive layer 204 may have a single-layer structure or may have a multi-layer structure in which layers are stacked in the third direction DR3.

Each of the first conductive layer 202 and the second conductive layer 204 of a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), indium zinc tin oxide (IZTO), or the like. Besides, the transparent conductive layer may include a conductive polymer such as poly(3,4-ethylenedioxythiophene) (PEDOT), a metal nano wire, graphene, and the like.

Each of the first conductive layer 202 and the second conductive layer 204 of the multi-layer structure may include metal layers. For example, the metal layers may have a three-layer structure of titanium/aluminum/titanium. The conductive layer of the multi-layer structure may include at least one metal layer and at least one transparent conductive layer.

At least one of the sensing insulating layer 203 and the cover insulating layer 205 may include an inorganic film. The inorganic film may include at least one of aluminum oxide, titanium oxide, silicon oxide, silicon nitride, silicon oxynitride, zirconium oxide, and hafnium oxide.

At least one of the sensing insulating layer 203 and the cover insulating layer 205 may include an organic film. The organic film may include at least one of acrylate-based resin, methacrylate-based resin, polyisoprene, vinyl-based resin, epoxy-based resin, urethane-based resin, cellulose-based resin, siloxane-based resin, polyimide-based resin, polyamide-based resin, and perylene-based resin.

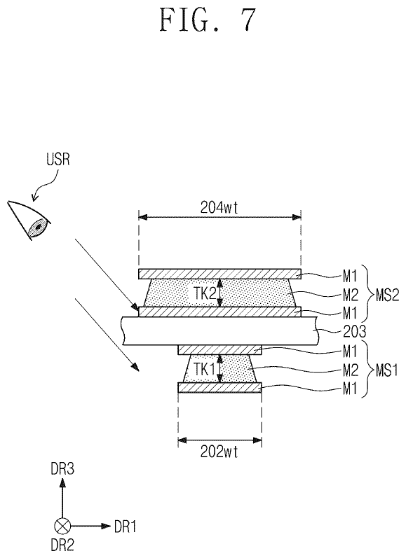

FIG. 7 is a cross-sectional view of a sensor layer, according to some embodiments of the present disclosure.

Referring to FIGS. 6 and 7, a second width 204wt of a second mesh line MS2 included in the second conductive layer 204 may be greater than or equal to a first width 202wt of a first mesh line MS1 included in the first conductive layer 202. When a user USR watches the first mesh line MS1 and the second mesh line MS2 from a side, the first mesh line MS1 has a smaller width than the second mesh line MS2, and thus the probability that the first mesh line MS1 is to be perceived by the user USR may be reduced.

Each of the first mesh line MS1 and the second mesh line MS2 may include first metal layers M1 and a second metal layer M2 interposed between the first metal layers M1. The first metal layers M1 may include titanium (Ti), and the second metal layer M2 may include aluminum (Al). However, this is only an example and is not particularly limited thereto.

According to some embodiments of the present disclosure, a first thickness TK1 of the second metal layer M2 of the first mesh line MS1 and a second thickness TK2 of the second metal layer M2 of the second mesh line MS2 may be the same (or substantially the same) as each other, but are not particularly limited thereto. For example, the first thickness TK1 may be thicker than the second thickness TK2. Alternatively, the second thickness TK2 may be thicker than the first thickness TK1. According to some embodiments of the present disclosure, each of the first thickness TK1 and the second thickness TK2 may be 1000 Ångström or more, and for example, 6000 Ångström.

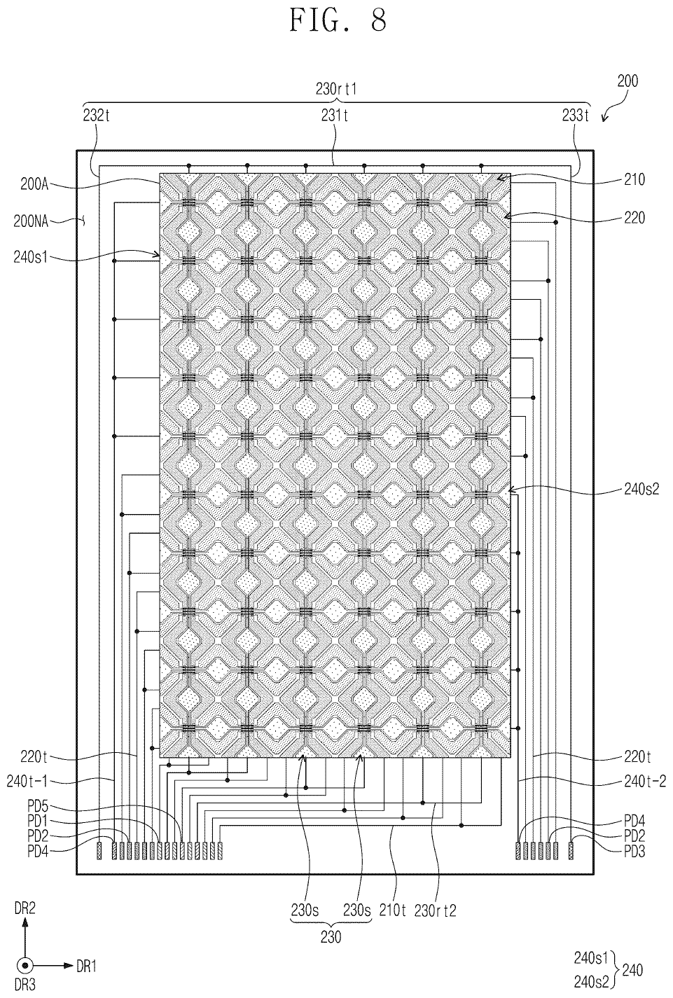

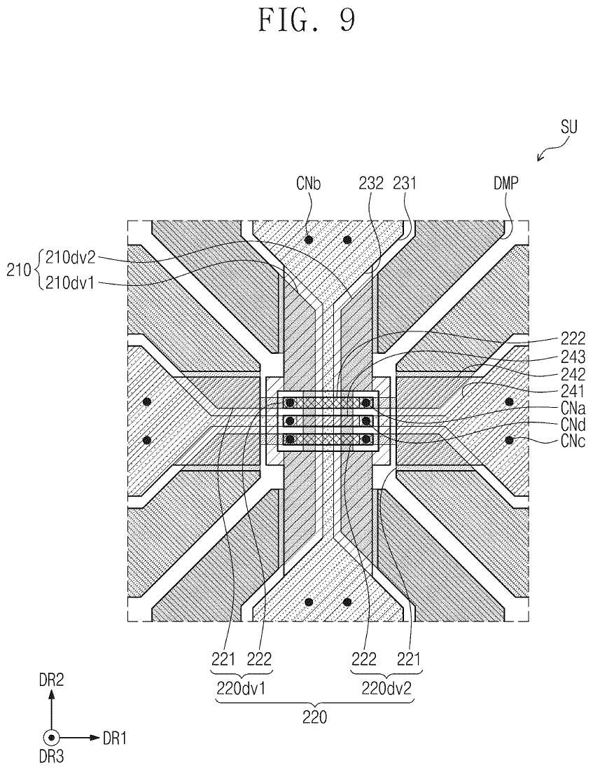

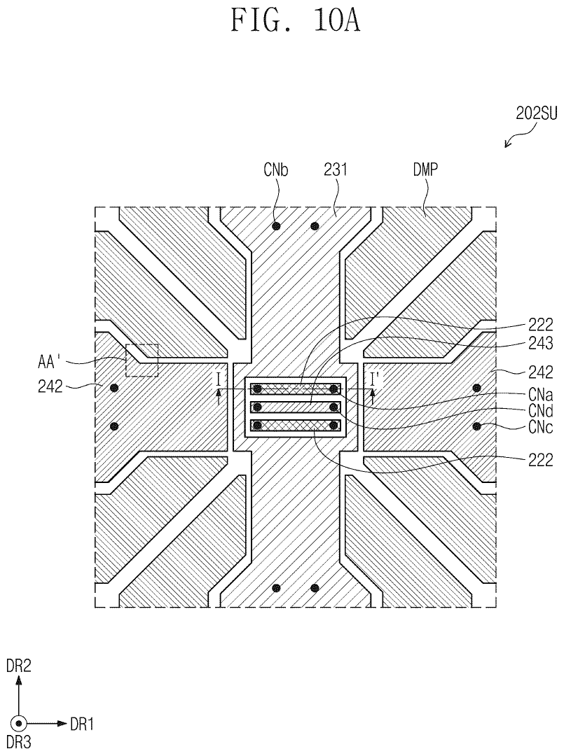

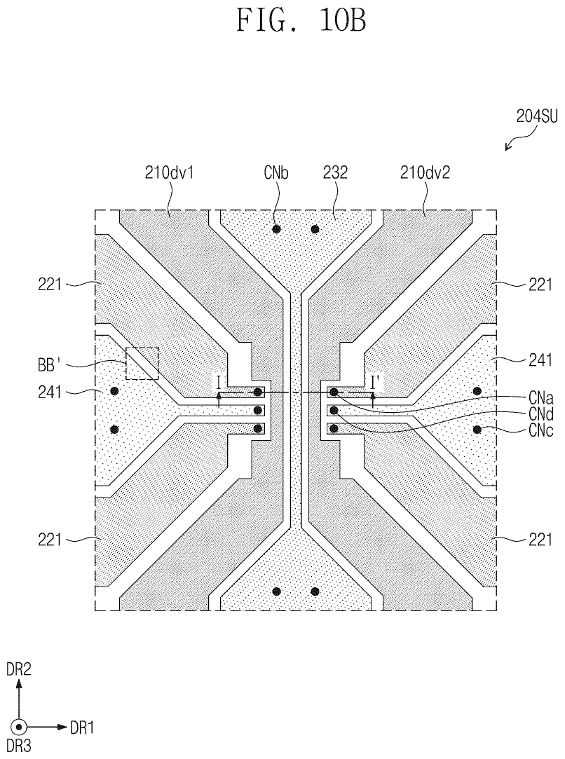

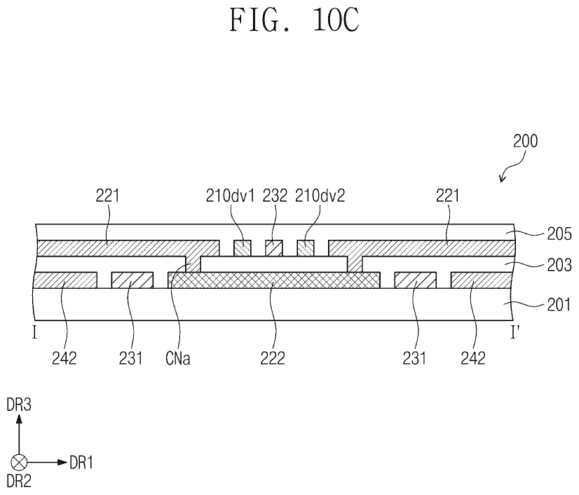

FIG. 8 is a plan view of a sensor layer, according to some embodiments of the present disclosure. FIG. 9 is an enlarged plan view of one sensing unit, according to some embodiments of the present disclosure. FIG. 10A is a plan view showing a first conductive layer of a sensing unit, according to some embodiments of the present disclosure. FIG. 10B is a plan view showing a second conductive layer of a sensing unit, according to some embodiments of the present disclosure. FIG. 10C is a cross-sectional view of a sensor layer taken along the line I-I′ illustrated in FIGS. 10A and 10B, according to some embodiments of the present disclosure.

Referring to FIG. 8, a sensing area 200A and a peripheral area 200NA adjacent to the sensing area 200A may be defined in the sensor layer 200.

The sensor layer 200 may include a plurality of first electrodes 210, a plurality of second electrodes 220, a plurality of third electrodes 230, and a plurality of fourth electrodes 240, which are located in the sensing area 200A.

The plurality of first electrodes 210 and the plurality of second electrodes 220 may be referred to as the touch electrodes 210 and 220. The plurality of third electrodes 230 and the plurality of fourth electrodes 240 may be referred to as the pen electrodes 230 and 240.

The first electrodes 210 may intersect the second electrodes 220. Each of the first electrodes 210 may extend in the second direction DR2. The first electrodes 210 may be arranged spaced from each other in the first direction DR1. Each of the second electrodes 220 may extend in the first direction DR1. The second electrodes 220 may be arranged spaced from each other in the second direction DR2. A sensing unit SU of the sensor layer 200 may be an area where the one first electrode 210 intersects the one second electrode 220.

FIG. 8 illustrates the six first electrodes 210 and the ten second electrodes 220, and illustrates the 60 sensing units SU. However, the number of first electrodes 210 and the number of second electrodes 220 are not limited thereto.

Referring to FIGS. 8 and 9, each of the first electrodes 210 may include first division electrodes 210dv1 and 210dv2. The first division electrodes 210dv1 and 210dv2 may extend in the second direction DR2 and may be spaced from each other in the first direction DR1. The first division electrodes 210dv1 and 210dv2 may have a line-symmetrical shape with respect to a line extending in the second direction DR2.

Each of the second electrodes 220 may include second division electrodes 220dv1 and 220dv2. The second electrodes 220 extend in the first direction DR1 and may be spaced from each other in the second direction DR2. The second division electrodes 220dv1 and 220dv2 may have a line-symmetrical shape with respect to a line extending in the first direction DR1.

Referring to FIGS. 9, 10A, 10B, and 10C, each of the second division electrodes 220dv1 and 220dv2 may include a sensing pattern 221 and a bridge pattern 222. The sensing pattern 221 and the bridge pattern 222 may be located on different layers, and the sensing pattern 221 and the bridge pattern 222 may be electrically connected to each other through a first contact CNa. For example, the bridge pattern 222 may be included in a first conductive layer 202SU. The sensing pattern 221 and the first division electrodes 210dv1 and 210dv2 may be included in a second conductive layer 204SU. The first conductive layer 202SU may be included in the first conductive layer 202 of FIG. 6, and the second conductive layer 204SU may be included in the second conductive layer 204 of FIG. 6.

Each of the third electrodes 230 may extend in the second direction DR2. The third electrodes 230 may be arranged spaced from each other in the first direction DR1. According to some embodiments of the present disclosure, each of the third electrodes 230 may include a plurality of first auxiliary electrodes 230s that are electrically connected in parallel. The number of first auxiliary electrodes 230s included in each of the third electrodes 230 may be varied. For example, as the number of first auxiliary electrodes 230s included in each of the third electrodes 230 increases, the resistance of each of the third electrodes 230 is lowered. Accordingly, power efficiency may be relatively improved and sensing sensitivity may be relatively improved. On the other hand, as the number of first auxiliary electrodes 230s included in each of the third electrodes 230 decreases, the loop coil pattern formed by using the third electrodes 230 may be implemented in diverse forms.

FIG. 8 illustrates that the one third electrode 230 includes the two first auxiliary electrodes 230s, but embodiments according to the present disclosure are not particularly limited thereto. The first auxiliary electrodes 230s may be arranged in a one-to-one correspondence with the first electrodes 210. Accordingly, the one sensing unit SU may include a portion of the one first auxiliary electrode 230s.

A coupling capacitor may be defined between the one first electrode 210 and the one first auxiliary electrode 230s. In this case, the current induced when a pen is sensed may be delivered from the first auxiliary electrode 230s to the first electrode 210 through the coupling capacitor. In other words, the first auxiliary electrode 230s may compensate for a signal delivered from the first electrode 210 to the sensor driver 200C. Accordingly, the greatest effect may be achieved when a phase of the signal induced in the first auxiliary electrode 230s matches a phase of the signal induced in the first electrode 210. Therefore, the center of each of the first electrodes 210 in the second direction DR2 may overlap the center of each of the first auxiliary electrodes 230s in the second direction DR2. Furthermore, the center of each of the first electrodes 210 in the first direction DR1 may overlap the center of each of the first auxiliary electrodes 230s in the first direction DR1.

According to some embodiments of the present disclosure, because the one third electrode 230 includes the two first auxiliary electrodes 230s, the one third electrode 230 may correspond to (or overlap) the two first electrodes 210. Accordingly, the number of first electrodes 210 included in the sensor layer 200 may be greater than the number of third electrodes 230. For example, the number of first electrodes 210 may be equal to the product of the number of third electrodes 230 included in the sensor layer 200 and the number of first auxiliary electrodes 230s included in each of the third electrodes 230. In FIG. 9, the number of first electrodes 210 may be 6; the number of third electrodes 230 may be 3; and the number of first auxiliary electrodes 230s included in each of the third electrodes 230 may be 2.

The fourth electrodes 240 may be arranged in the second direction DR2, and the fourth electrodes 240 may extend in the first direction DR1. According to some embodiments of the present disclosure, each of the fourth electrodes 240 may include second auxiliary electrodes 240s1 or 240s2 electrically connected to each other.

The routing directions of the second auxiliary electrode 240s1 and the second auxiliary electrode 240s2 may be different from each other. FIG. 9 illustrates the two fourth electrodes 240 and the five second auxiliary electrodes 240s1 or 240s2 included in each of the fourth electrodes 240.

In this specification, the fact that the routing directions are different from each other means that connection locations of electrodes and trace lines are different from each other. For example, a first connection location of a fourth trace line 240t-1 electrically connected to the second auxiliary electrode 240s1 may be different from a second connection location of a fourth trace line 240t-2 electrically connected to the second auxiliary electrode 240s2. The first connection location may be placed at a left end based on the second auxiliary electrode 240s1. The second connection location may be placed at a right end of the second auxiliary electrode 240s2.

According to some embodiments of the present disclosure, the sensor layer 200 may include one fourth electrode. In this case, the fourth electrode may include ten second auxiliary electrodes connected in parallel with each other. The number of second auxiliary electrodes is only described in the drawing illustrated in FIG. 8, and the number of second auxiliary electrodes included in the fourth electrode is not limited to the above-described example.

FIG. 8 shows that the five second auxiliary electrodes 240s1 are electrically connected to each other, and the five second auxiliary electrodes 240s2 are electrically connected to each other. That is, the area ratio of the two fourth electrodes 240 or the number ratio of the second auxiliary electrode included in each of the two fourth electrodes 240 may be a ratio of 1:1. However, embodiments according to the present disclosure are not particularly limited thereto. For example, the number of second auxiliary electrodes 240s1 may be different from the number of second auxiliary electrodes 240s2.

According to some embodiments of the present disclosure, when each of the fourth electrodes 240 includes the second auxiliary electrodes 240s1 or 240s2 connected in parallel, the area of one fourth electrode may be increased. Furthermore, as the resistance of each of the fourth electrodes 240 is lowered, the sensing sensitivity for the second input 3000 (see FIG. 5) may be relatively improved.

A coupling capacitor may be defined between the one second electrode 220 and the one second auxiliary electrode 240s1. In this case, the current induced when a pen is sensed may be delivered from the second auxiliary electrode 240s1 to the second electrode 220 through the coupling capacitor. In other words, the second auxiliary electrode 240s1 may compensate for a signal delivered from the second electrode 220 to the sensor driver 200C. Accordingly, the greatest effect may be achieved when a phase of the signal induced in the second auxiliary electrode 240s1 matches a phase of the signal induced in the second electrode 220. Therefore, the center of each of the second electrodes 220 in the first direction DR1 may overlap the center of each of the second auxiliary electrodes 240s1 in the first direction DR1. Moreover, the center of each of the second electrodes 220 in the second direction DR2 may overlap the center of each of the second auxiliary electrodes 240s1 in the second direction DR2.

Referring to FIGS. 8, 10A, and 10B, each of the first auxiliary electrodes 230s included in the third electrode 230 may include a 3-1st pattern 231 and a 3-2nd pattern 232. The 3-1st pattern 231 and the 3-2nd pattern 232 may be placed on different layers. The 3-1st pattern 231 and the 3-2nd pattern 232 may be electrically connected to each other through a second contact CNb. The 3-1st pattern 231 may be included in the first conductive layer 202SU. The 3-2nd pattern 232 may be included in the second conductive layer 204SU.

According to some embodiments of the present disclosure, a part of the 3-1st pattern 231 may overlap a part of each of the first division electrodes 210dv1 and 210dv2. Accordingly, coupling capacitance may be provided (or formed) between the first electrode 210 and the third electrode 230.

The second auxiliary electrodes 240s1 or 240s2 included in the fourth electrode 240 may include a 4-1st pattern 241, a 4-2nd pattern 242, and a 4-3rd pattern 243. The 4-2nd pattern 242 and the 4-3rd pattern 243 may be placed on the same layer as each other. The 4-1st pattern 241 may be placed on a different layer from the 4-2nd pattern 242 and the 4-3rd pattern 243. The 4-1st pattern 241 and the 4-2nd pattern 242 may be electrically connected to each other through a third contact CNc. The 4-1st pattern 241 and the 4-3rd pattern 243 may be electrically connected to each other through a fourth contact CNd. The 4-2nd pattern 242, and the 4-3rd pattern 243 may be included in the first conductive layer 202SU, and the 4-1st pattern 241 may be included in the second conductive layer 204SU.

According to some embodiments of the present disclosure, a part of the 4-2nd pattern 242 may overlap the sensing pattern 221 of each of the second division electrodes 220dv1 and 220dv2. Accordingly, coupling capacitor may be defined (or provided/formed) between the second electrode 220 and the fourth electrode 240.

According to some embodiments of the present disclosure, the first conductive layer 202SU may further include dummy patterns DMP. Each of the dummy patterns DMP may be electrically floated or electrically grounded. According to some embodiments of the present disclosure, the dummy patterns DMP may be omitted. Because the dummy patterns DMP are placed in the empty space, the probability that a specific pattern is visually perceived due to external light reflection may be reduced. In other words, the electronic device 1000 (see FIG. 1A) with relatively improved visibility according to external light reflection may be provided.

The sensor layer 200 may further include a plurality of first trace lines 210t placed in the peripheral area 200NA, a plurality of first pads PD1 connected to the first trace lines 210t in a one-to-one correspondence, a plurality of second trace lines 220t, and a plurality of second pads PD2 connected to the second trace lines 220t in a one-to-one correspondence.

The first trace lines 210t may be electrically connected to the first electrodes 210 in a one-to-one correspondence. The two first division electrodes 210dv1 and 210dv2 included in the one first electrode 210 may be connected to one of the first trace lines 210t. Each of the first trace lines 210t may include a plurality of branch units to be connected to the two first division electrodes 210dv1 and 210dv2. According to some embodiments of the present disclosure, the two first division electrodes 210dv1 and 210dv2 may be connected to each other within the sensing area 200A.

The second trace lines 220t may be electrically connected to the second electrodes 220 in a one-to-one correspondence. The two second division electrodes 220dv1 and 220dv2 included in the one second electrode 220 may be connected to one of the second trace lines 220t. Each of the second trace lines 220t may include a plurality of branch units to be connected to the two second division electrodes 220dv1 and 220dv2. According to some embodiments of the present disclosure, the two second division electrodes 220dv1 and 220dv2 may be connected to each other within the sensing area 200A.

The sensor layer 200 may further include a third trace line 230rt1 placed in the peripheral area 200NA, a plurality of third pads PD3 connected to one end and the other end of the third trace line 230rt1, the fourth trace lines 240t-1 and 240t-2, fourth pads PD4 connected to the fourth trace lines 240t-1 and 240t-2 in a one-to-one correspondence, fifth trace lines 230rt2, and fifth pads PD5 connected to the fifth trace lines 230rt2 in a one-to-one correspondence.

The third trace line 230rt1 may be electrically connected to the at least one first auxiliary electrode 230s of the first auxiliary electrodes 230s. According to some embodiments of the present disclosure, the third trace line 230rt1 may be electrically connected to all of the first auxiliary electrodes 230s. In other words, the third trace line 230rt1 may be electrically connected to all of the third electrodes 230. The third trace line 230rt1 may include a first line portion 231t extending in the first direction DR1 and electrically connected to the third electrodes 230, a second line portion 232t extending from a first end of the first line portion 231t in the second direction DR2, and a third line portion 233t extending from a second end of the first line portion 231t in the second direction DR2.

According to some embodiments of the present disclosure, each of the resistance of the second line portion 232t and the resistance of the third line portion 233t may be the same (or substantially the same) as the resistance of one third electrode among the third electrodes 230. Accordingly, the second line portion 232t and the third line portion 233t may serve as the third electrodes 230, and the same effect that the third electrodes 230 are also placed in the peripheral area 200NA may be obtained. For example, one of the second line portion 232t and the third line portion 233t and one of the third electrodes 230 may form a coil. Accordingly, a pen located in an area adjacent to the peripheral area 200NA may also be sufficiently charged by a loop including the second line portion 232t or the third line portion 233t.

According to some embodiments of the present disclosure, to adjust the resistance of each of the second line portion 232t and the third line portion 233t, the width of each of the second line portion 232t and the third line portion 233t in the first direction DR1 may be adjusted. However, this is only an example, and the first to third line portions 231t, 232t, and 233t may have the same (or substantially the same) width as each other.

The fifth trace lines 230rt2 may be connected to the third electrodes 230 in a one-to-one correspondence. In other words, the number of fifth trace lines 230rt2 may correspond to the number of third electrodes 230. In FIG. 9, the three fifth trace lines 230rt2 are shown.

According to some embodiments of the present disclosure, the fifth trace lines 230rt2 and the fifth pad PD5 may be omitted, and a charging driving mode for charging a pen may be omitted. In this case, the sensor layer 200 may sense an input from an active-type pen capable of emitting a magnetic field even when the magnetic field is not provided from the sensor layer 200.

The fourth trace lines 240t-1 and 240t-2 may be spaced from each other with the sensing area 200A therebetween. The fourth trace line 240t-1 may be electrically connected to the at least one second auxiliary electrode 240s1 among the second auxiliary electrodes 240s1. For example, one end of each of the second auxiliary electrodes 240s1 may be connected to the fourth trace line 240t-1. The fourth trace line 240t-2 may be electrically connected to the at least one second auxiliary electrode 240s2 among the second auxiliary electrodes 240s2. For example, one end of each of the second auxiliary electrodes 240s2 may be connected to the fourth trace line 240t-2.

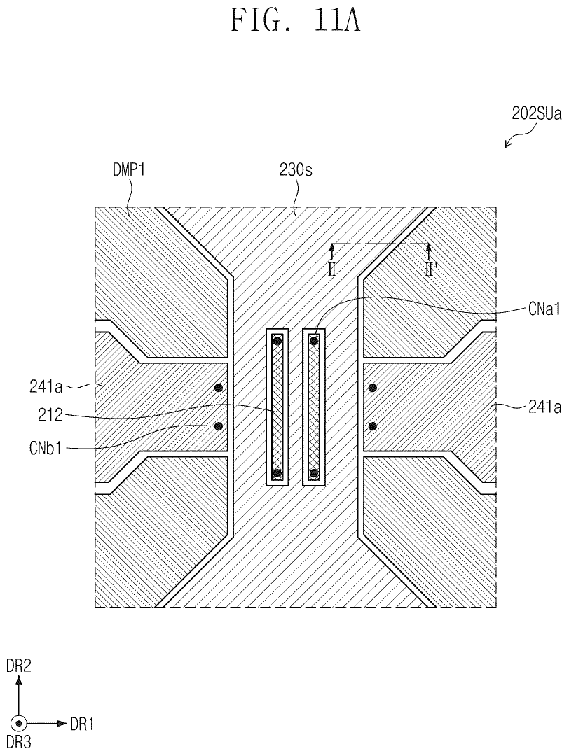

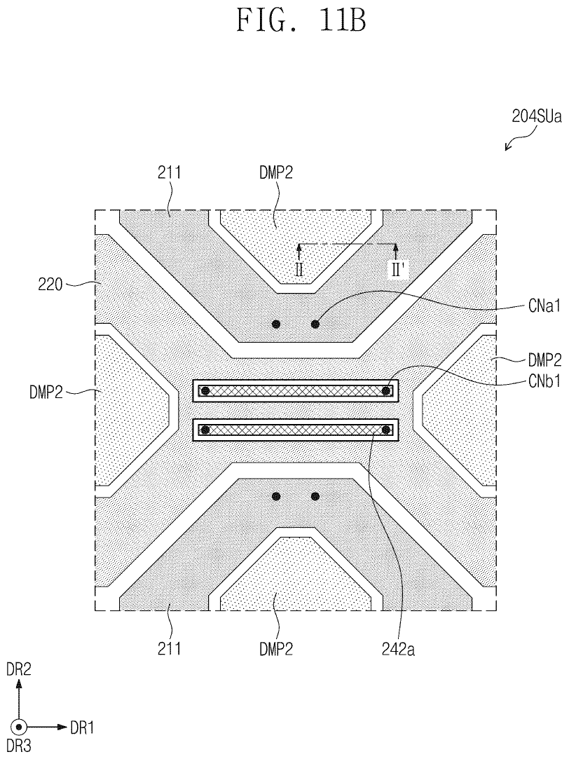

FIG. 11A is a plan view showing a first conductive layer of a sensing unit, according to some embodiments of the present disclosure. FIG. 11B is a plan view showing a second conductive layer of a sensing unit, according to some embodiments of the present disclosure. FIG. 11C is a cross-sectional view of a sensor layer taken along the line II-II′ illustrated in FIGS. 11A and 11B, according to some embodiments of the present disclosure.

Referring to FIGS. 8, 9, 11A, 11B, and 11C, each of the plurality of first electrodes 210 may include a plurality of first sensing patterns 211 and a plurality of first bridge patterns 212. The first sensing patterns 211 may be spaced apart from one another in the second direction DR2, and the first bridge patterns 212 may extend in the second direction DR2 and may be electrically connected to the first sensing patterns 211 through first contacts CNa1. Although FIGS. 11A and 11B illustrate an example that the two first sensing patterns 211 adjacent to each other are electrically connected with each other by the two first bridge patterns 212, embodiments according to the present disclosure are not particularly limited thereto. For example, the two first sensing patterns 211 adjacent to each other may be electrically connected with each other by the one first bridge pattern 212 or may be electrically connected with each other by the three or more first bridge patterns 212.

The first sensing patterns 211 adjacent to each other in the second direction DR2 may be spaced apart from each other with the plurality of second electrodes 220 therebetween. According to some embodiments of the present disclosure, the first sensing patterns 211 and the second electrode 220 may be included in a second conductive layer 204SUa, and the first bridge patterns 212 may be included in a first conductive layer 202SUa. The first bridge patterns 212 may be insulated from the second electrode 220 overlapping the first bridge patterns 212 and may cross the first bridge patterns 212.

Each of first auxiliary electrodes 230s included in each of the plurality of third electrodes 230 may extend in the second direction DR2. The first auxiliary electrodes 230s may be included in the first conductive layer 202SUa. One or more holes may be defined in each of the first auxiliary electrodes 230s. One first bridge pattern 212 may be located in one hole. Accordingly, the first bridge pattern 212 may be electrically insulated from the first auxiliary electrodes 230s.

Each of second auxiliary electrodes 240s1 or 240s2 included in each of the plurality of fourth electrodes 240 may include a plurality of second sensing patterns 241a and a plurality of second bridge patterns 242a. The second sensing patterns 241a may be spaced apart from one another in the first direction DR1, and the second bridge patterns 242a may extend in the first direction DR1 and may be electrically connected to the second sensing patterns 241a through second contacts CNb1.

Although FIGS. 11A and 11B illustrate an example that the two second sensing patterns 241a adjacent to each other are electrically connected with each other by the two second bridge patterns 242a, embodiments according to the present disclosure are not particularly limited thereto. For example, the two second sensing patterns 241a adjacent to each other may be electrically connected with each other by the one second bridge pattern 242a or may be electrically connected with each other by the three or more second bridge patterns 242a.

According to some embodiments of the present disclosure, the second sensing patterns 241a and the first auxiliary electrodes 230s may be included in the first conductive layer 202SUa, and the second bridge patterns 242a may be included in the second conductive layer 204SUa. The second bridge patterns 242a may be insulated from the first auxiliary electrodes 230s overlapping the second bridge patterns 242a and may cross the first auxiliary electrodes 230S.

The area occupied by components included in the plurality of first electrodes 210 and the plurality of second electrodes 220 in the second conductive layer 204SUa of the one sensing unit SU may be greater than the area occupied by components included in the plurality of third electrodes 230 and the plurality of fourth electrodes 240. A change in capacitance due to the first input 2000 (see FIG. 5) may be greater as a distance becomes shorter. Accordingly, components for sensing the first input 2000 (see FIG. 5) may be arranged in a layer adjacent to the surface of the electronic device 1000 (see FIG. 1A) to have a relatively great area. As a result, touch performance may be relatively improved.

According to some embodiments of the present disclosure, the first conductive layer 202SUa may further include first dummy patterns DMP1, and the second conductive layer 204SUa may further include second dummy patterns DMP2. The first dummy patterns DMP1 and the second dummy patterns DMP2 may be floated or may be electrically floated. The first dummy patterns DMP1 and the second dummy patterns DMP2 may each be divided into a plurality of conductive patterns. For example, the one first dummy pattern DMP1 may include a plurality of floating dummy patterns separated or electrically isolated from one another.

The area of the first auxiliary electrode 230s and the area of the first sensing pattern 211 may be adjusted. For example, the position of the boundary between the first auxiliary electrode 230s and the first dummy patterns DMP1 and the position of the boundary between the first sensing pattern 211 and the second dummy patterns DMP2 may be adjusted. In this case, the area of the overlapping area between the first auxiliary electrode 230s and the first sensing pattern 211 may be adjusted, and the magnitude of the capacitance of a coupling capacitor C-CP between the first auxiliary electrode 230s and the first sensing pattern 211 may be adjusted accordingly.

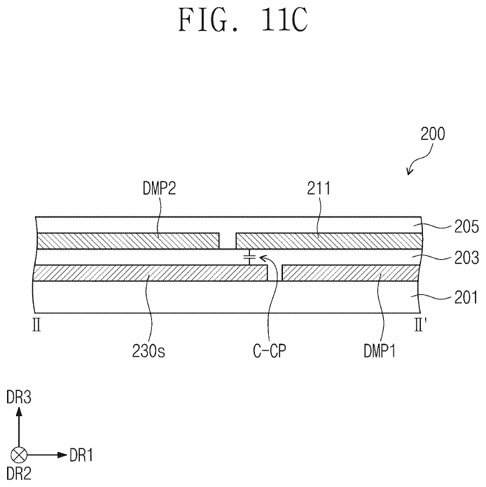

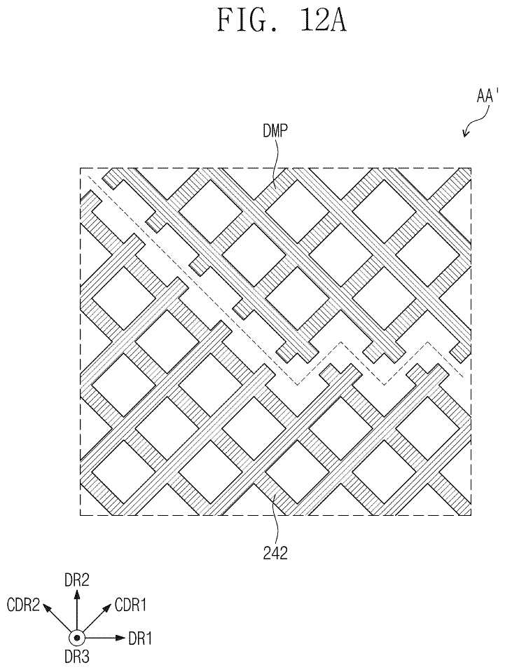

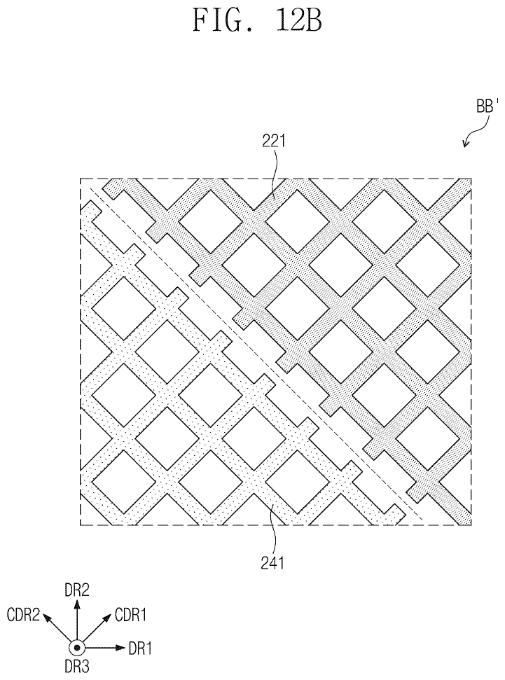

FIG. 12A is an enlarged plan view of area AA′ shown in FIG. 10A, according to some embodiments of the present disclosure. FIG. 12B is an enlarged plan view of area BB′ shown in FIG. 10B, according to some embodiments of the present disclosure.

Referring to FIGS. 10A, 10B, 12A, and 12B, first electrode groups 210G, second electrode groups 220G, third electrode groups 230G, fourth electrode groups 240G, and the dummy patterns DMP may each have a mesh structure. Each of the mesh structures may include a plurality of mesh lines. Each of the plurality of mesh lines may have a shape extending in a certain direction. The plurality of mesh lines may be connected with one another. The shape may have various shapes such as a straight line, a line having protrusions, and an uneven line. Openings in which no mesh structure is located may be defined (provided or formed) in each of the plurality of first electrodes 210, the plurality of second electrodes 220, the plurality of third electrodes 230, the plurality of fourth electrodes 240, and the dummy patterns DMP.

FIGS. 12A and 12B illustrate that the mesh structure includes mesh lines extending in a first cross direction CDR1 intersecting the first direction DR1 and the second direction DR2, and mesh lines extending in the second cross direction CDR2 intersecting the first cross direction CDR1. However, the extension direction of the mesh lines constituting the mesh structure is not particularly limited to the illustrations in FIGS. 12A and 12B. For example, the mesh structure may include only mesh lines extending in the first direction DR1 and the second direction DR2, or may include mesh lines extending in the first direction DR1, the second direction DR2, and the first cross direction CDR1 and the second cross direction CDR2. In other words, the mesh structure may be changed into various forms.

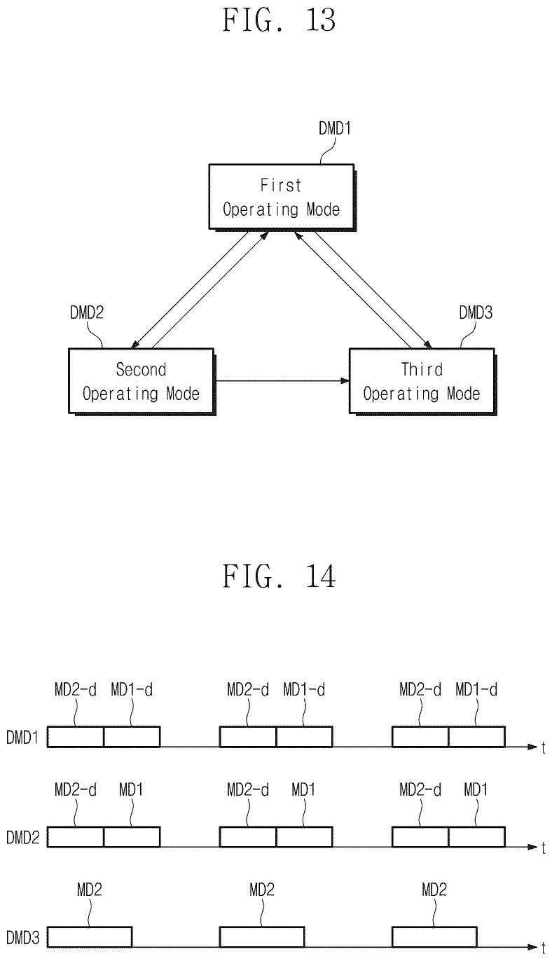

FIG. 13 is a view illustrating an operation of a sensor driver, according to some embodiments of the present disclosure.

Referring to FIGS. 5 and 13, the sensor driver 200C may be configured to selectively operate in one of a first operating mode DMD1, a second operating mode DMD2, and a third operating mode DMD3.

The first operating mode DMD1 may be referred to as a “touch and pen standby mode”; the second operating mode DMD2 may be referred to as a “touch activation and pen standby mode”; and, the third operating mode DMD3 may be referred to as a “pen activation mode”. The first operating mode DMD1 may be a mode for waiting for the first input 2000 and the second input 3000. The second operating mode DMD2 may be a mode for sensing the first input 2000 and waiting for the second input 3000. The third operating mode DMD3 may be a mode for sensing the second input 3000.

According to some embodiments of the present disclosure, the sensor driver 200C may be first driven in the first operating mode DMD1. When the first input 2000 is sensed in the first operating mode DMD1, the operating mode of the sensor driver 200C may be switched (or changed) to the second operating mode DMD2. Alternatively, when the second input 3000 is sensed in the first operating mode DMD1, the operating mode of the sensor driver 200C may be switched (or changed) to the third operating mode DMD3.

According to some embodiments of the present disclosure, when the second input 3000 is sensed in the second operating mode DMD2, an operating mode of the sensor driver 200C may be switched to the third operating mode DMD3. When the first input 2000 is terminated (or not sensed) in the second operating mode DMD2, an operating mode of the sensor driver 200C may be switched to the first operating mode DMD1. When the second input 3000 is terminated (or not detected) in the third operating mode DMD3, an operating mode of the sensor driver 200C may be switched to the first operating mode DMD1.

FIG. 14 is a view illustrating an operation of a sensor driver, according to some embodiments of the present disclosure.

Referring to FIGS. 5, 8, 13, and 14, operations in the first to third operating modes DMD1, DMD2, and DMD3 are illustrated in order of time (t).

In the first operating mode DMD1, the sensor driver 200C may repeatedly operate in a second mode MD2-d and a first mode MD1-d. During the second mode MD2-d, the sensor layer 200 may perform a scan driving operation to detect the second input 3000. During the first mode MD1-d, the sensor layer 200 may perform a scan driving operation to detect the first input 2000. FIG. 14 illustrates that the sensor driver 200C operates in the first mode MD1-d continuously after the second mode MD2-d, but the order is not limited thereto.

In the second operating mode DMD2, the sensor driver 200C may repeatedly operate in the second mode MD2-d and a first mode MD1. During the second mode MD2-d, the sensor layer 200 may perform a scan driving operation to detect the second input 3000. During the first mode MD1, the sensor layer 200 may perform a scan driving operation to detect coordinates corresponding to the first input 2000.

In the third operating mode DMD3, the sensor driver 200C may operate in a second mode MD2. During the second mode MD2, the sensor layer 200 may perform a scan driving operation to detect coordinates corresponding to the second input 3000. In the third operating mode DMD3, the sensor driver 200C may not operate in the first mode MD1-d or MD1 until the second input 3000 is terminated (or not sensed).

In the first mode MD1-d and the first mode MD1, the third electrodes 230 and the fourth electrodes 240 may all be grounded. Accordingly, touch noise may be prevented from being introduced through the third electrodes 230 and the fourth electrodes 240.

In the second mode MD2-d and the second mode MD2, first ends of the third electrodes 230 and the fourth electrodes 240 may all be floated. In addition, in the second mode MD2-d and the second mode MD2, second ends of the third electrodes 230 and the fourth electrodes 240 may all be grounded or floated. Accordingly, compensation of the sensing signal may be maximized by the coupling between the first electrodes 210 and the third electrodes 230 and the coupling between the second electrodes 220 and the fourth electrodes 240.

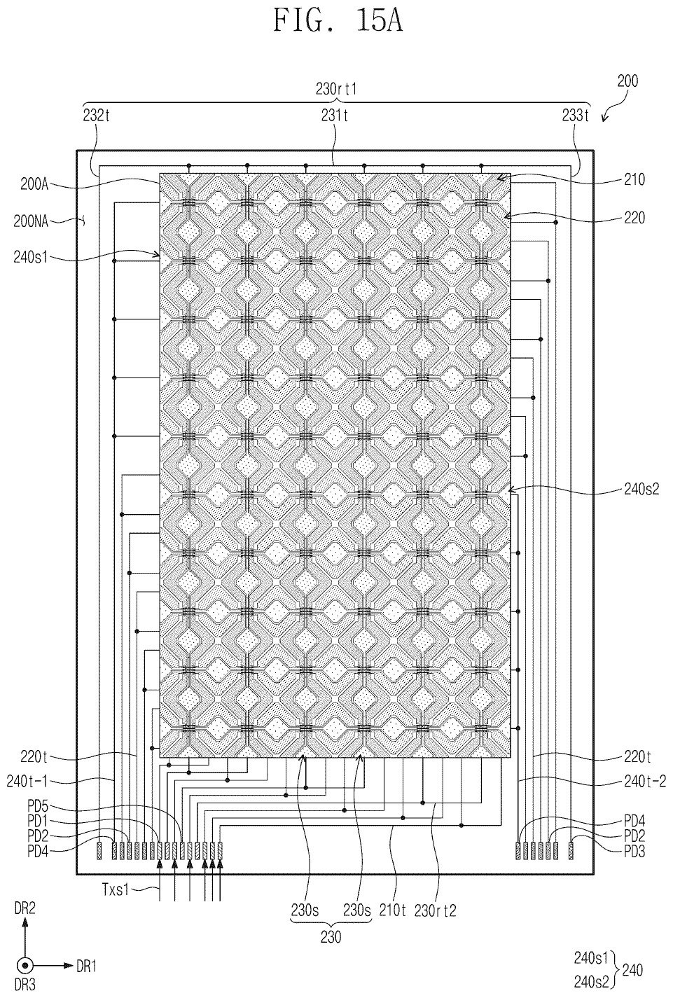

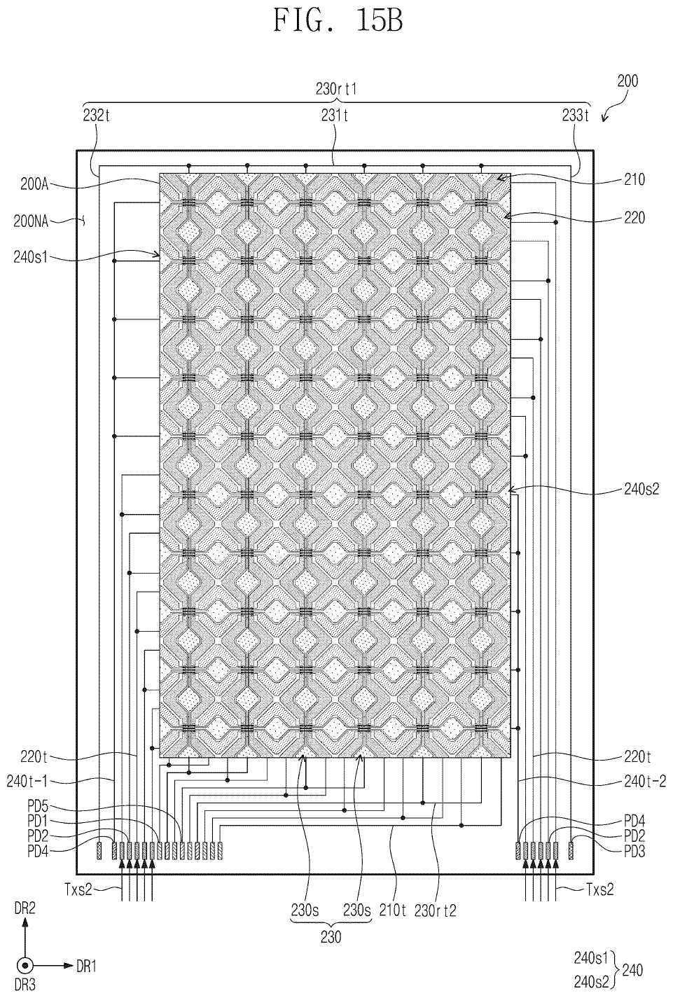

FIGS. 15A and 15B are views for describing a first mode, according to some embodiments of the present disclosure.

Referring to FIGS. 14, 15A, and 15B, the first mode MD1-d and the first mode MD1 may include a self-capacitance detection mode. The self-capacitance detection mode may include a first sub-section and a second sub-section. FIG. 15A is a view for describing an operation in the first sub-section, and FIG. 15B is a view for describing an operation in the second sub-section.

In the self-capacitance detection mode, the sensor driver 200C may be configured to calculate input coordinates by outputting driving signals Txs1 and Txs2 to the first electrodes 210 and the second electrodes 220 and sensing a change in capacitance of each of the first electrodes 210 and the second electrodes 220. Referring to FIG. 15A, in the first sub-section, the sensor driver 200C may output the driving signal Txs1 to the first trace lines 210t. Referring to FIG. 15B, in the second sub-section, the sensor driver 200C may output the driving signal Txs2 to the second trace lines 220t.

The third electrodes 230 are electrically connected with the third trace line 230rt1 and the fifth trace lines 230rt2, and the fourth electrodes 240 are electrically connected with the fourth trace lines 240t-1 and 240t-2. In the self-capacitance detection mode, the third electrodes 230 and the fourth electrodes 240 may all be grounded. Accordingly, noise may not be introduced through the third electrodes 230 and the fourth electrodes 240.

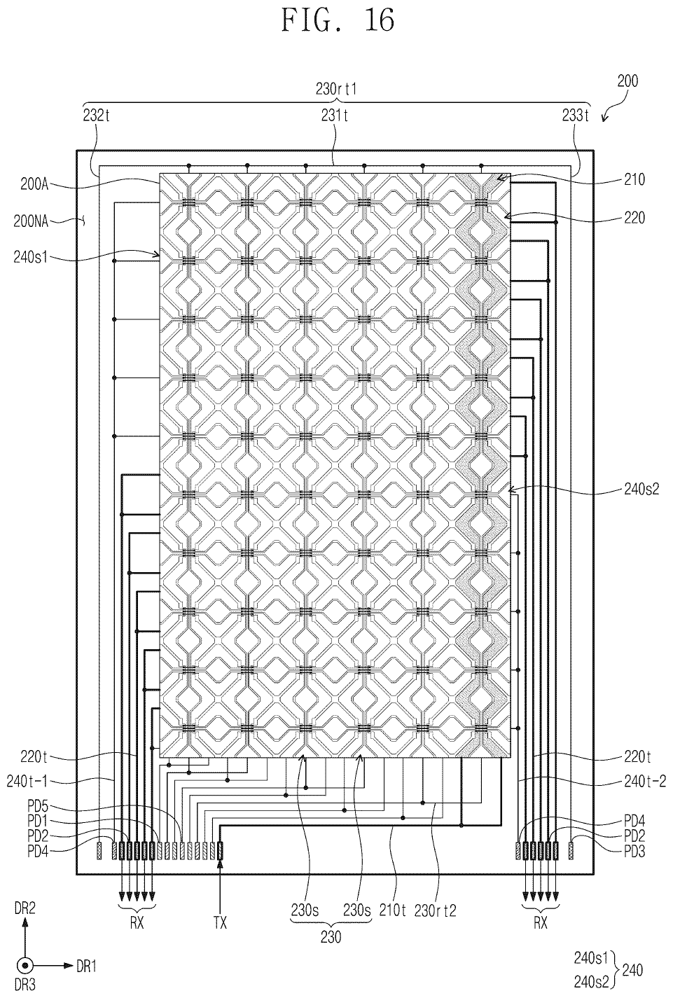

FIG. 16 is a diagram for describing a first mode, according to some embodiments of the present disclosure.

Referring to FIGS. 5, 14, and 16, the first mode MD1-d and the first mode MD1 may further include a mutual-capacitance detection mode. FIG. 16 is a diagram for describing the mutual-capacitance detection mode in the first mode MD1-d and the first mode MD1.

In the mutual-capacitance detection mode, the sensor driver 200C may sequentially provide a transmission signal TX to the first electrodes 210, and may detect coordinates for the first input 2000 by using a reception signal RX detected through the second electrodes 220. For example, the sensor driver 200C may be configured to calculate input coordinates by sensing changes in mutual capacitance between the first electrodes 210 and the second electrodes 220.

FIG. 16 illustrates that the transmission signal TX is provided to the one first electrode 210, and the reception signal RX is output from the second electrodes 220. To clarify the expression of a signal, FIG. 16 illustrates that only the one first electrode 210 to which the transmission signal TX is provided is hatched. The sensor driver 200C may detect input coordinates of the first input 2000 by sensing changes in capacitance between the first electrode 210 and each of the second electrodes 220.

In the mutual-capacitance detection mode, both the third electrodes 230 and the fourth electrodes 240 may be grounded. Accordingly, noise may not be introduced through the third electrodes 230 and the fourth electrodes 240.

In each of the first mode MD1-d and the first mode MD1, the sensor layer 200 may alternately repeat the operations described with reference to FIGS. 15A, 15B, and 16. However, this is only an example and is not particularly limited thereto. For example, in each of the first mode MD1-d and the first mode MD1, the sensor layer 200 may repeat only the operation described with reference to FIG. 14. Alternatively, in the first mode MD1-d, the sensor layer 200 may repeat only at least one of the operations described with reference to FIGS. 15A, 15B, and 16, and in the first mode MD1, the sensor layer 200 may alternately repeat the operations described with reference to FIGS. 15A, 15B, and 16.

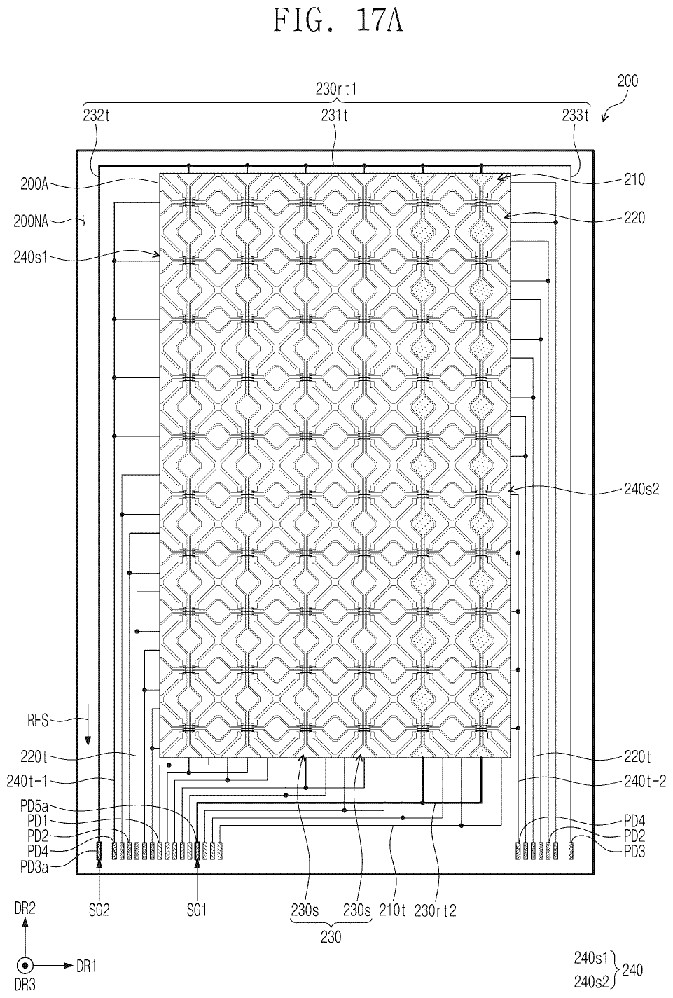

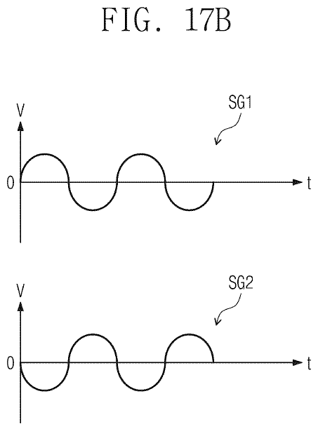

FIG. 17A is a diagram for describing a second mode, according to some embodiments of the present disclosure. FIG. 17B are graphs illustrating waveforms of a first signal and a second signal, according to some embodiments of the present disclosure.

Referring to FIGS. 5, 14, 17A, and 17B, the second mode MD2 may include a charging driving mode and a pen sensing driving mode.

In the charging driving mode, the sensor driver 200C may apply a first charging signal SG1 to at least one pad of the third pads PD3 and the fifth pads PD5 and may apply a second charging signal SG2 to the at least other pad. The second charging signal SG2 may be a reverse signal of the first charging signal SG1. Each of the first charging signal SG1 and the second charging signal SG2 may be a sinusoidal wave. However, this is an example. For example, the waveform of each of the first charging signal SG1 and the second charging signal SG2 according to some embodiments of the present disclosure is not limited thereto. For example, each of the first charging signal SG1 and the second charging signal SG2 may be a square wave.

Although FIG. 17A illustrates an example that the first charging signal SG1 is applied to one pad and the second charging signal SG2 is applied to another pad, embodiments according to the present disclosure are not limited thereto. For example, the first charging signal SG1 may be applied to two or more pads, and the second charging signal SG2 may be applied to two or more other pads.

Because the first charging signal SG1 and the second charging signal SG2 are applied to at least two pads, current RFS may have a current path through at least one pad to the at least one other pad. Furthermore, because the first charging signal SG1 and the second charging signal SG2 are sinusoidal signals having a reverse-phase relationship to each other, the direction of the current RFS may change periodically.

The first charging signal SG1 and the second charging signal SG2 may have the reverse-phase relationship. Accordingly, noise caused in the display layer 100 by the first charging signal SG1 may cancel out noise caused by the second charging signal SG2. Accordingly, a flicker may not occur in the display layer 100, and the display quality of the display layer 100 may be relatively improved.

It is shown that the second charging signal SG2 is provided to one third pad PD3a connected to one third trace line 230rt1, and the first charging signal SG1 is provided to one fifth pad PD5a connected to the third electrode 230. The current RFS may flow through a current path defined by the fifth pad PD5a, the fifth trace line 230rt2 connected to the fifth pad PD5a, the third electrode 230, a portion of the third trace line 230rt1 connected to the third pad PD3a, and the third pad PD3a. The current path may have the form of a coil. Accordingly, in the charging driving mode of the second mode, the resonant circuit of the pen PN may be charged by the current path. In this case, the plurality of third electrodes 230 may be referred to as a “plurality of channels”, respectively.

According to some embodiments of the present disclosure, a current path of the loop coil pattern may be implemented by the components included in the sensor layer 200. Accordingly, the electronic device 1000 may charge the pen PN by using the sensor layer 200. Thus, a configuration having a coil for charging the pen PN does not need to be separately added such that an increase in the thickness and weight of the electronic device 1000 and a decrease in the flexibility of the electronic device 1000 may not occur.

In the charging driving mode, the first electrodes 210, the second electrodes 220, and the fourth electrodes 240 may be grounded or electrically floated or may receive a constant voltage. In particular, the first electrodes 210, the second electrodes 220, and the fourth electrodes 240 may be floated. In this case, the current RFS may not flow to the first electrodes 210, the second electrodes 220, and the fourth electrodes 240.

The charging driving mode may include a searching charging driving mode and a tracking charging driving mode.

Because the position of the pen PN is not sensed in the searching charging driving mode, the first charging signal SG1 or the second charging signal SG2 may be sequentially provided to all channels included in the sensor layer 200. For example, the first charging signal SG1 and the second charging signal SG2 may be sequentially scanned in the first direction DR1. That is, in the searching charging driving mode, the entire sensing area 200A of the sensor layer 200 may be scanned.

When the pen PN is sensed in the searching charging driving mode, the sensor layer 200 may be driven for tracking charging. For example, in the tracking charging driving mode, the sensor driver 200C may sequentially output the first charging signal SG1 and the second charging signal SG2 to an area overlapping a point where the pen PN is sensed, not the entire sensor layer 200.

Accordingly, after the position of the pen PN is sensed, channels that are driven for charging may be limited in correspondence to the position of the pen PN in the previous frame. Thus, channels overlapping an area where the pen is not located may not be driven for charging such that the efficiency of charging operation may be relatively improved.

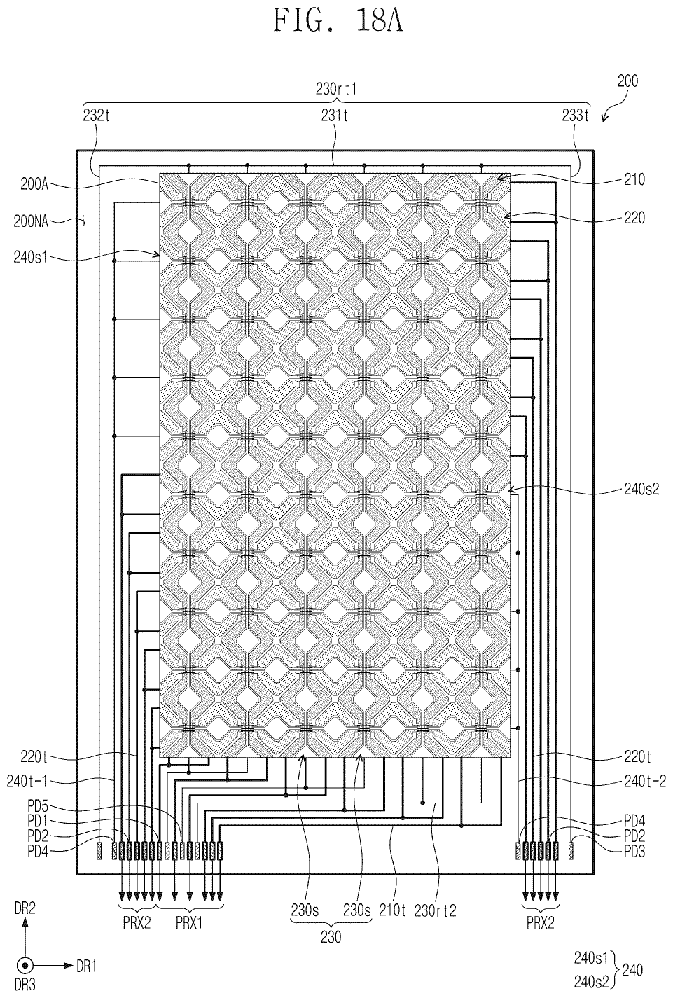

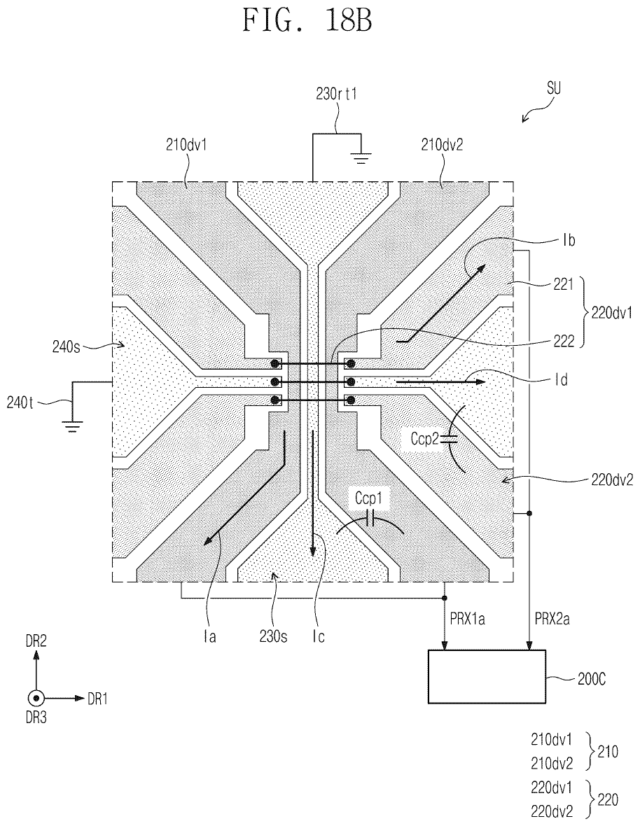

FIG. 18A is a diagram for describing a second mode, according to some embodiments of the present disclosure. FIG. 18B is a diagram for describing a second mode based on a sensing unit, according to some embodiments of the present disclosure.

Referring to FIGS. 5, 18A, and 18B, in the second mode, the charging driving mode and the pen sensing driving mode may be alternately repeated. FIG. 18B shows the one sensing unit SU through which first to fourth induced currents Ia, Ib, Ic, and Id generated by the pen PN flow.

An RLC resonant circuit of the pen PN may emit a magnetic field at a resonant frequency while discharging charged charges. Due to the magnetic field provided by the pen PN, the first induced current Ia may be generated in the first electrode 210, and the second induced current Ib may be generated in the second electrode 220. Moreover, the third induced current Ic may be generated in the first auxiliary electrode 230s of the third electrode 230, and the fourth induced current Id may also be generated in the second auxiliary electrode 240s of the fourth electrode 240. The second auxiliary electrode 240s may be the second auxiliary electrode 240s1 or 240s2 illustrated in FIG. 18A.

A first coupling capacitor Ccp1 may be formed between the first auxiliary electrode 230s and the first electrode 210. A second coupling capacitor Cop2 may be formed between the second auxiliary electrode 240s and the second electrode 220. The third induced current Ic may be delivered to the first electrode 210 through the first coupling capacitor Ccp1. The fourth induced current Id may be delivered to the second electrode 220 through the second coupling capacitor Ccp2. In this case, the plurality of first electrodes 210 and the plurality of second electrodes 220 may each be referred to as a “channel”.

The sensor driver 200c may receive a first sensing signal PRX1a based on the first induced current Ia and the third induced current Ic from the first electrode 210 and may receive a second sensing signal PRX2a based on the second induced current Ib and the fourth induced current Id from the second electrode 220.

The first sensing signal PRX1a and the second sensing signal PRX2a may be provided in a sinusoidal wave form by the first to fourth induced currents Ia, Ib, Ic, and Id.

In other words, the sensor driver 200C may receive the first sensing signal PRX1a from the plurality of first electrodes 210 and may receive the second sensing signal PRX2a from the plurality of second electrodes 220. The sensor driver 200C may detect the coordinates of the pen PN, based on the first sensing signal PRX1a and/or the second sensing signal PRX2a.

The sensor driver 200C may receive the first sensing signal PRX1a from the first electrodes 210 and may receive the second sensing signal PRX2a from the second electrodes 220. In this case, all ends of the third electrodes 230 and the fourth electrodes 240 may be floated. Accordingly, compensation of the sensing signal may be maximized by the coupling between the first electrodes 210 and the third electrodes 230 and the coupling between the second electrodes 220 and the fourth electrodes 240. Besides, the other ends of the third electrodes 230 and the fourth electrodes 240 may be grounded or floated. Accordingly, the third induced current Ic and the fourth induced current Id may be sufficiently delivered to the first electrodes 210 and the second electrodes 220 by the coupling between the first electrodes 210 and the third electrodes 230 and by the coupling between the second electrodes 220 and the fourth electrodes 240.

According to some embodiments of the present disclosure, the routing directions of an electrode and an auxiliary electrode of the sensor layer 200 that overlap each other may be different from each other. For example, the routing direction of the first electrode 210 may be different from the routing direction of the first auxiliary electrode 230s. Also, the routing direction of the second electrode 220 may be different from the routing direction of the second auxiliary electrode 240s. For example, in FIG. 18B, the first electrode 210 and the first trace line 210t may be connected on the lower side of the sensing unit SU, and the first auxiliary electrode 230s and the third trace line 230rt1 may be connected on the upper side of the sensing unit SU. The second electrode 220 and the second trace line 220t may be connected on the left side of the sensing unit SU. The second auxiliary electrode 240s and the fourth trace line 240t may be connected on the right side of the sensing unit SU.

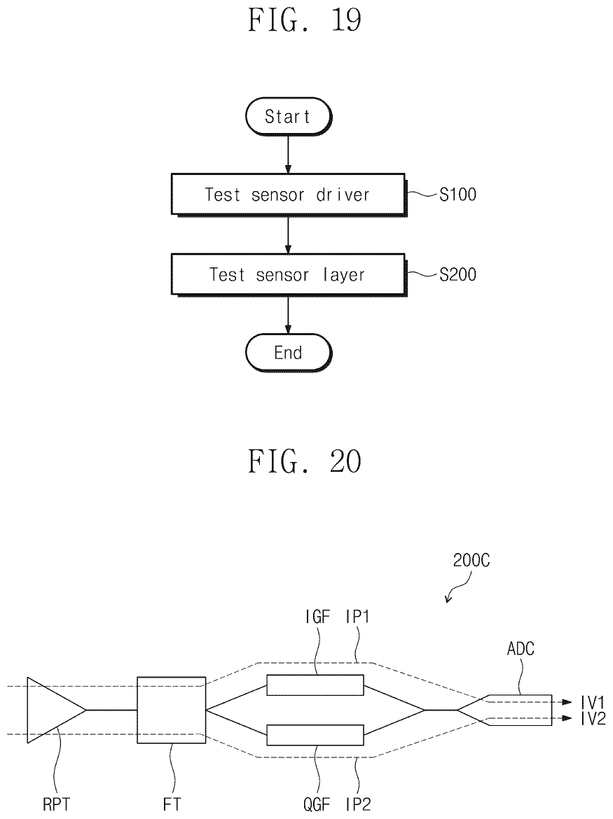

FIG. 19 is a flowchart illustrating an electronic device testing method, according to some embodiments of the present disclosure.

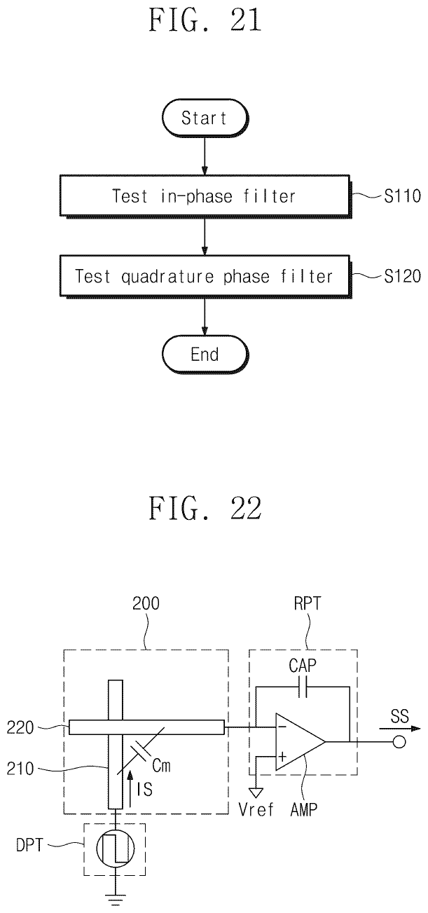

Referring to FIGS. 5 and 19, an electronic device testing method may include an operation of providing the electronic device 1000 including the sensor layer 200 and the sensor driver 200C driving the sensor layer 200, and an operation of testing the electronic device 1000 as the sensor driver 200C transmits a test signal IS (see FIG. 21) to the sensor layer 200.

The operation of testing the electronic device 1000 may include operation S100 of testing the sensor driver 200C and operation S200 of testing the sensor layer 200.

FIG. 20 is a block diagram illustrating a sensor driver, according to some embodiments of the present disclosure.

Referring to FIGS. 5 and 20, the sensor driver 200C may include a sensing unit RPT, a filter unit FT, an in-phase filter IGF, a quadrature phase filter QGF, and an analog-to-digital converter ADC.

The sensing unit RPT may be electrically connected to the sensor layer 200. The sensing unit RPT may include an amplifier AMP. The amplifier AMP may include a current-to-current or current-to-voltage (CC/CV) amplifier.

The filter unit FT may be connected to the sensing unit RPT. The filter unit FT may cancel noise from a signal received by the sensing unit RPT. The filter unit FT may include a low pass filter. For example, the filter unit FT may cancel high-frequency noise of the signal received by the sensing unit RPT.

The in-phase filter IGF may be electrically connected to the sensing unit RPT. For example, the in-phase filter IGF may be connected to the sensing unit RPT with the filter unit FT therebetween. The in-phase filter IGF may separate an in-phase component of the signal received by the sensing unit RPT.

The quadrature phase filter QGF may be electrically connected to the sensing unit RPT. For example, the quadrature phase filter QGF may be connected to the sensing unit RPT with the filter unit FT therebetween. The quadrature phase filter QGF may separate a quadrature phase component of the signal received by the sensing unit RPT.

According to some embodiments of the present disclosure, each of the first sensing signal PRX1a (see FIG. 18B) and the second sensing signal PRX2a (see FIG. 18B) input from the pen PN may have a sinusoidal wave. Each of the first sensing signal PRX1a (see FIG. 18B) and the second sensing signal PRX2a (see FIG. 18B) may be sensitive to phase delay. For this reason, the sensor driver 200C needs to perform IQ demodulation to interpret a signal. The in-phase filter IGF and the quadrature phase filter QGF may perform IQ demodulation on the pen input. Accordingly, it may be possible to provide the electronic device 1000 capable of interpreting the second input 3000 of the pen PN.

For example, the magnitude of each of the first sensing signal PRX1a (see FIG. 18B) and the second sensing signal PRX2a (see FIG. 18B) may be defined as the square root of the sum of the square of the in-phase component and the square of the quadrature phase component.

The analog-to-digital converter ADC may be connected to the in-phase filter IGF and the quadrature phase filter QGF. The analog-to-digital converter ADC may convert an analog signal into a digital signal.

The sensing unit RPT, the filter unit FT, the in-phase filter IGF, the quadrature phase filter QGF, and the analog-to-digital converter ADC may be configured as an analog front end.

FIG. 21 is a flowchart illustrating a method for testing a sensor driver, according to some embodiments of the present disclosure. FIG. 22 is a diagram schematically illustrating a sensor layer and a sensor driver, according to some embodiments of the present disclosure.

Referring to FIGS. 5 and 20 to 22, operation S100 (see FIG. 19) of testing the sensor driver 200C may include operation S110 of testing the in-phase filter IGF and operation S120 of testing the quadrature phase filter QGF.

The sensor driver 200C may further include a driver DPT. The driver DPT may output the test signal IS to the sensor layer 200.

The sensing unit RPT may include the amplifier AMP and a capacitor CAP.

A first input terminal of the amplifier AMP may be connected to the plurality of second electrodes 220.

A second input terminal of the amplifier AMP may be connected to a voltage supply unit having a voltage level (e.g., a set or predetermined voltage level). A reference voltage Vref may be provided to the second input terminal through the voltage supply unit. However, this is an example. For example, a voltage level provided to the second input terminal according to some embodiments of the present disclosure is not limited thereto. For example, a ground voltage may be provided to the second input terminal.

A sensing signal SS output through an output terminal of the amplifier AMP may be filtered through the filter unit FT, the in-phase filter IGF, and the quadrature phase filter QGF. The signal thus filtered afterwards may be converted into a digital signal through the analog-to-digital converter ADC.

The capacitor CAP may be connected between the first input terminal and the output terminal of the amplifier AMP.

In operation S100 (see FIG. 19) of testing the sensor driver 200C, the driver DPT may be electrically connected to the plurality of first electrodes 210, and the sensing unit RPT may be electrically connected to the plurality of second electrodes 220.

The driver DPT may transmit the test signal IS to at least one of the plurality of first electrodes 210.

The sensing unit RPT may receive the sensing signal SS for the test signal IS from at least one of the plurality of second electrodes 220.

The sensing signal SS may correspond to the mutual capacitance of a capacitor Cm formed between the plurality of first electrodes 210 and the plurality of second electrodes 220. The sensing signal SS may be referred to as “raw data”.

In operation S110 of testing the in-phase filter IGF, the sensing signal SS may be output as a first test value IV1 through a first test path IP1.

The first test path IP1 may be a path passing through the sensing unit RPT, the filter unit FT, the in-phase filter IGF, and the analog-to-digital converter ADC.

The first test value IV1 may correspond to the mutual capacitance of the capacitor Cm formed between the plurality of first electrodes 210 and the plurality of second electrodes 220.

The first test value IV1 may be provided to the analysis unit 200C1. The analysis unit 200C1 may determine whether the first test value IV1 is within a normal range.

For example, when the first test value IV1 is within a range (e.g., a set or predetermined range), the analysis unit 200C1 may determine that the in-phase filter IGF is normal. When the first test value IV1 is outside the range (e.g., the set or predetermined range), the analysis unit 200C1 may determine that the in-phase filter IGF is abnormal.

In this case, the range (e.g., the set or predetermined range), which is a range of the mutual capacitance of the capacitor Cm, which is determined to be normal by the analysis unit 200C1, may be determined by measuring, in advance, mutual capacitance, and may vary depending on the characteristics or configuration of the sensor layer 200 and the sensor driver 200C.

In operation S120 of testing the quadrature phase filter QGF, the sensing signal SS may be output as a second test value IV2 through a second test path IP2.

The second test path IP2 may be a path passing through the sensing unit RPT, the filter unit FT, the quadrature phase filter QGF, and the analog-to-digital converter ADC.

The second test value IV2 may correspond to the mutual capacitance of the capacitor Cm formed between the plurality of first electrodes 210 and the plurality of second electrodes 220.

The second test value IV2 may be provided to the analysis unit 200C1. The analysis unit 200C1 may compare the first test value IV1 and the second test value IV2.

The analysis unit 200C1 may determine whether the second test value IV2 is similar to the first test value IV1. When the second test value IV2 is within the normal range as with the first test value IV1, the analysis unit 200C1 may determine that the quadrature phase filter QGF is good or operating normally (or operating according to an intended operation or function).

When the first test value IV1 is within the normal range, and the second test value IV2 is outside the normal range, the analysis unit 200C1 may determine that the quadrature phase filter QGF is abnormal.

According to some embodiments of the present disclosure, whether a sinusoidal signal is capable of being interpreted without inputting a signal by using the pen PN may be determined through operation S120 of testing the quadrature phase filter QGF. In other words, it may be possible to relatively easily determine whether the sensor driver 200C is capable of interpreting the second input 3000 without the pen PN. Accordingly, a process of testing the sensor driver 200C may be relatively simplified, and the test time may be shortened.

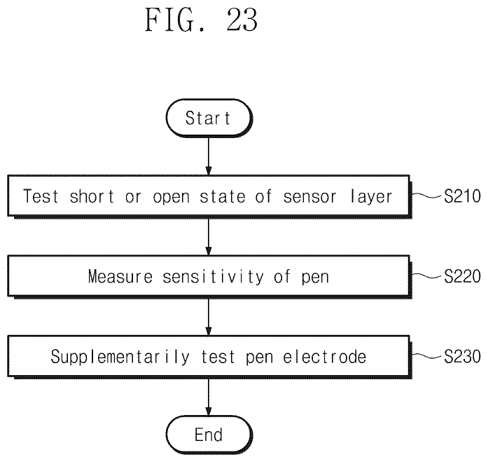

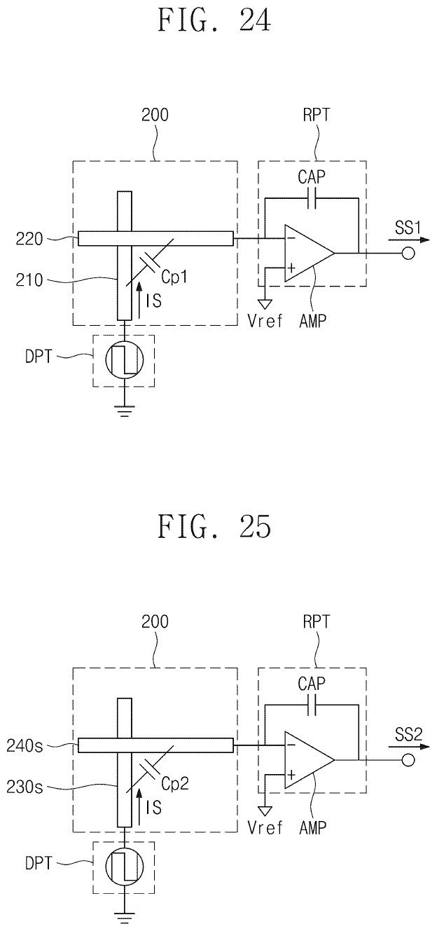

FIG. 23 is a flowchart illustrating a method for testing a sensor layer, according to some embodiments of the present disclosure. FIGS. 24 and 25 are diagrams schematically illustrating a sensor layer and a sensor driver, according to some embodiments of the present disclosure. In the description of FIGS. 24 and 25, the same reference numerals are assigned to the same components described with reference to FIG. 22, and thus the descriptions thereof are omitted.

Referring to FIGS. 5 and 23 to 25, operation S200 (see FIG. 19) of testing the sensor layer 200 may include operation S210 of testing a short or open state of the sensor layer 200, operation S220 of measuring sensitivity of the pen PN, and operation S230 of supplementarily testing the pen electrodes 230 and 240.

Operation S210 of testing the short or open state of the sensor layer 200 may include an operation of testing the short state of the sensor layer 200 and an operation of testing the open state of the sensor layer 200.

The operation of testing the short state of the sensor layer 200 may include an operation of testing short states of the touch electrodes 210 and 220 and an operation of testing short states of the pen electrodes 230 and 240.

In the operation of testing the short states of the touch electrodes 210 and 220, the driver DPT may be electrically connected to the plurality of first electrodes 210, and the sensing unit RPT may be electrically connected to the plurality of second electrodes 220.

The driver DPT may transmit the test signal IS to at least one of the plurality of first electrodes 210.

The sensing unit RPT may receive a first sensing signal SS1 for the test signal IS from each of the plurality of second electrodes 220. The first sensing signal SS1 may correspond to the mutual capacitance of a first capacitor Cp1 formed between the plurality of first electrodes 210 and the plurality of second electrodes 220.

The first sensing signal SS1 may be provided to the analysis unit 200C1. The first sensing signal SS1 may be referred to as “raw data”.

The analysis unit 200C1 may test the short states of the touch electrodes 210 and 220 based on the first sensing signal SS1. For example, when connecting the shorted touch electrode among the touch electrodes 210 and 220 to two or more lines in parallel, the first sensing signal SS1 measured at a touch electrode surrounding the shorted touch electrode may indicate 0 or the maximum value. However, this is an example. For example, a method for testing the short states of the touch electrodes 210 and 220 according to some embodiments of the present disclosure is not limited thereto and may be measured in various ways.

The first sensing signal SS1 measured in the operation of testing the short states of the touch electrodes 210 and 220 may be referred to as a “1-1st sensing signal”.

In the operation of testing the short states of the pen electrodes 230 and 240, the driver DPT may be electrically connected to the plurality of first auxiliary electrodes 230s, and the sensing unit RPT may be electrically connected to the plurality of second auxiliary electrodes 240s.

The driver DPT may transmit the test signal IS to at least one of the plurality of first auxiliary electrodes 230s.

The sensing unit RPT may receive a second sensing signal SS2 for the test signal IS from each of the plurality of second auxiliary electrodes 240s. The second sensing signal SS2 may correspond to the mutual capacitance of a second capacitor CP2 formed between the plurality of first auxiliary electrodes 230s and the plurality of second auxiliary electrodes 240s.

The second sensing signal SS2 may be provided to the analysis unit 200C1. The second sensing signal SS2 may be referred to as “raw data”.

The analysis unit 200C1 may test the short states of the pen electrodes 230 and 240 based on the second sensing signal SS2. The analysis unit 200C1 may test the short states of the pen electrodes 230 and 240 in the same method as a method of testing the short states of the touch electrodes 210 and 220.

The second sensing signal SS2 measured in the operation of testing the short states of the pen electrodes 230 and 240 may be referred to as a “2-1st sensing signal”.

The operation of testing the open state of the sensor layer 200 may include an operation of testing open states of the touch electrodes 210 and 220 and an operation of testing open states of the pen electrodes 230 and 240.

In the operation of testing the open states of the touch electrodes 210 and 220, the driver DPT may be electrically connected to the plurality of first electrodes 210, and the sensing unit RPT may be electrically connected to the plurality of second electrodes 220.

The driver DPT may transmit the test signal IS to at least one of the plurality of first electrodes 210.

The sensing unit RPT may receive the first sensing signal SS1 for the test signal IS from each of the plurality of second electrodes 220.

The first sensing signal SS1 may be provided to the analysis unit 200C1.

The analysis unit 200C1 may test the open states of the touch electrodes 210 and 220 based on the first sensing signal SS1. For example, the first sensing signal SS1 measured at a touch electrode, in which an open occurs, from among the touch electrodes 210 and 220 may indicate 0. The first sensing signal SS1 measured at a touch electrode surrounding the touch electrode, in which the open occurs, may indicate a maximum value. However, this is an example. For example, a method for testing the open states of the touch electrodes 210 and 220 according to some embodiments of the present disclosure is not limited thereto and may be measured in various ways.

The first sensing signal SS1 measured in the operation of testing the open states of the touch electrodes 210 and 220 may be referred to as a “1-2nd sensing signal”.

In the operation of testing the open states of the pen electrodes 230 and 240, the driver DPT may be electrically connected to the plurality of first auxiliary electrodes 230s, and the sensing unit RPT may be electrically connected to the plurality of second auxiliary electrodes 240s.

The driver DPT may transmit the test signal IS to at least one of the plurality of first auxiliary electrodes 230s.

The sensing unit RPT may receive the second sensing signal SS2 for the test signal IS from each of the plurality of second auxiliary electrodes 240s.

The second sensing signal SS2 may be provided to the analysis unit 200C1. The analysis unit 200C1 may test the open states of the pen electrodes 230 and 240 based on the second sensing signal SS2. The analysis unit 200C1 may test the open states of the pen electrodes 230 and 240 in the same way as the open states of the touch electrodes 210 and 220.

The second sensing signal SS2 measured at the operation of testing the open states of the pen electrodes 230 and 240 may be referred to as a “2-2nd sensing signal”.

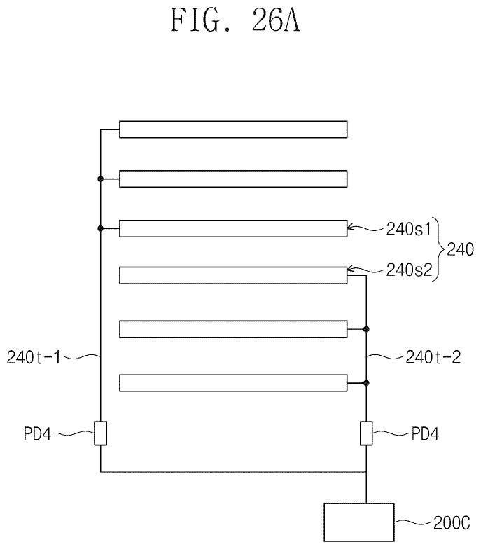

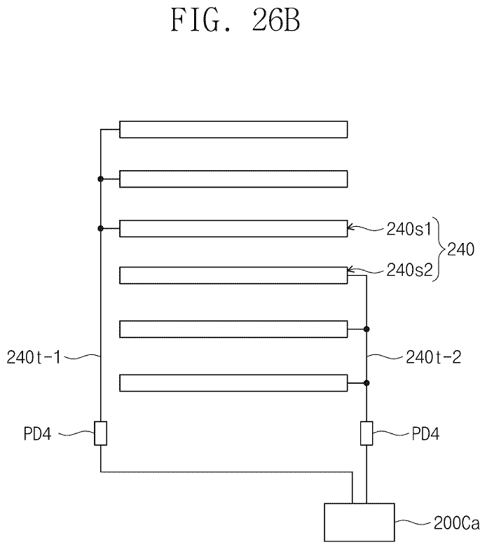

FIG. 26A is a drawing for describing a connection relationship between a plurality of fourth electrodes and a sensor driver, according to some embodiments of the present disclosure. In the description of FIG. 26A, the same reference numerals are assigned to the same components described with reference to FIG. 8, and thus the descriptions thereof are omitted.

Referring to FIG. 26A, in the first mode MD1 (see FIG. 14) and the second mode MD2 (see FIG. 14), a separate sensing signal may not be received from the plurality of fourth electrodes 240.

Unlike embodiments of the present disclosure, in a conventional configuration where there is no method for testing the pen electrodes 230 and 240, the sensor driver 200C may not require pads connected to correspond to the plurality of fourth electrodes 240. However, according to some embodiments of the present disclosure, the short or open state of the pen electrodes 230 and 240 may be tested based on the second sensing signal SS2 by receiving the second sensing signal SS2 from the plurality of fourth electrodes 240. Accordingly, a connection is required between the plurality of fourth pads PD4 and pads inside the sensor driver 200C.

The plurality of fourth pads PD4 may be connected to one pad of the sensor driver 200C. The plurality of fourth pads PD4 may be electrically connected to each other and may be connected to the sensor driver 200C.

According to some embodiments of the present disclosure, a method of connecting the pads PD4 and the pads inside the sensor driver 200C may be optimized. Accordingly, the electronic device 1000 (see FIG. 1A) having relatively improved reliability may be provided.

FIG. 26B is a drawing for describing a connection relationship between a plurality of fourth electrodes and a sensor driver, according to some embodiments of the present disclosure. In the description of FIG. 26B, the same reference numerals are assigned to the same components described with reference to FIG. 8, and thus the descriptions thereof are omitted.

Referring to FIG. 26B, the plurality of fourth pads PD4 may be connected to two pads inside the sensor driver 200C, respectively. Each of the plurality of fourth pads PD4 may be connected to the sensor driver 200C through different pads.

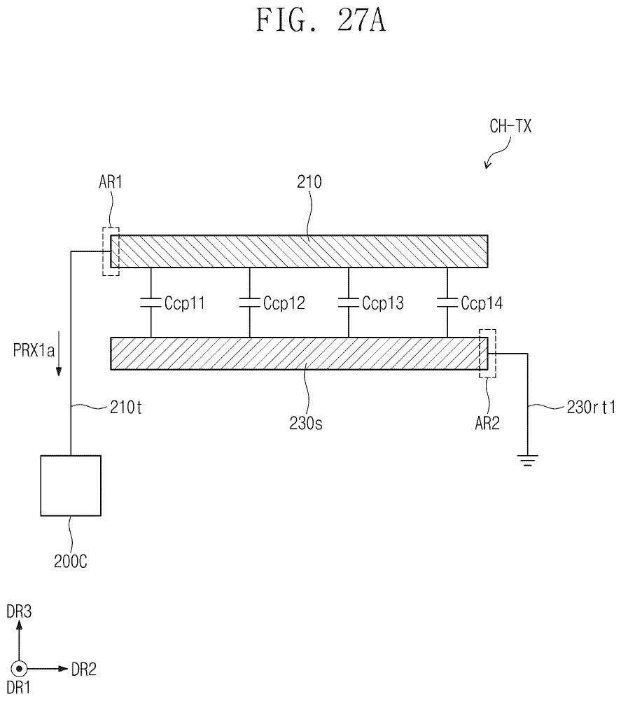

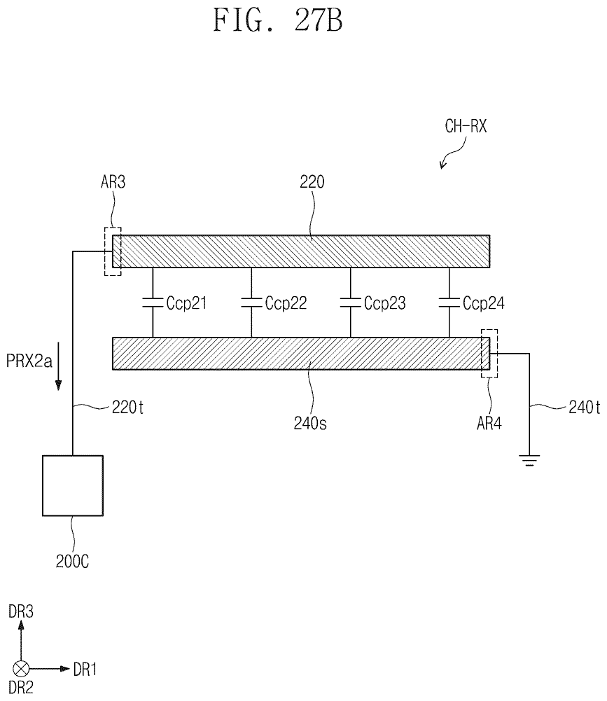

FIG. 27A is a diagram schematically illustrating one channel, according to some embodiments of the present disclosure.

Referring to FIGS. 8, 18B, and 27A, one first channel CH-TX is illustrated. For example, the one first channel CH-TX may include the first electrode 210 and the first auxiliary electrode 230s overlapping the first electrode 210. For example, when viewed in the third direction DR3, the first electrode 210 and the first auxiliary electrode 230s may overlap each other. The first electrode 210 may output the first sensing signal PRX1a to the sensor driver 200C, and the first auxiliary electrode 230s may be connected to the first electrode 210 in a coupling method.

According to some embodiments of the present disclosure, in a pen sensing driving mode, the first auxiliary electrode 230s may be electrically connected to a ground. For example, the third trace line 230rt1, which is electrically connected to the first auxiliary electrode 230s, may be grounded. In other words, the first auxiliary electrode 230s may be directly connected to the ground through the third trace line 230rt1.

The first electrode 210 may be connected to the first trace line 210t in a first area AR1. The first auxiliary electrode 230s may be connected to the third trace line 230rt1 in a second area AR2. Each of the first electrode 210 and the first auxiliary electrode 230s may extend in the second direction DR2, and the first area AR1 and the second area AR2 may be spaced from each other in the second direction DR2.

A plurality of first coupling capacitors Ccp11, Ccp12, Ccp13, and Ccp14 may be defined between the first electrode 210 and the first auxiliary electrode 230s. In a sensing mode, the sensor driver 200C may receive the induced current flowing from the first auxiliary electrode 230s to the first electrode 210 through the first coupling capacitors Ccp11, Ccp12, Ccp13, and Ccp14. In other words, each of the first coupling capacitors Ccp11, Ccp12, Ccp13, and Ccp14 may play the role of supplying current. Each of the first coupling capacitors Ccp11, Ccp12, Ccp13, and Ccp14 may indicate the sensitivity of the pen PN.

FIG. 27B is a diagram schematically illustrating one channel, according to some embodiments of the present disclosure.

Referring to FIGS. 8, 18B, and 27B, one second channel CH-RX is illustrated. For example, the one second channel CH-RX may include the second electrode 220 and the second auxiliary electrode 240s overlapping the second electrode 220. For example, when viewed in the third direction DR3, the second electrode 220 and the second auxiliary electrode 240s may overlap each other. The second electrode 220 may output the second sensing signal PRX2a to the sensor driver 200C, and the second auxiliary electrode 240s may be connected to the second electrode 220 in a coupling method.

According to some embodiments of the present disclosure, in a pen sensing driving mode, the second auxiliary electrode 240s may be electrically connected to a ground. For example, the fourth trace line 240t, which is electrically connected to the second auxiliary electrode 240s, may be grounded. That is, the second auxiliary electrode 240s may be directly connected to the ground through the fourth trace line 240t.

The second electrode 220 may be connected to the second trace line 220t in a third area AR3. The second auxiliary electrode 240s may be connected to the fourth trace line 240t in a fourth area AR4. Each of the second electrode 220 and the second auxiliary electrode 240s may extend in the first direction DR1, and the third area AR3 and the fourth area AR4 may be spaced from each other in the first direction DR1.

A plurality of second coupling capacitors Ccp21, Ccp22, Ccp23, and Ccp24 may be defined between the second electrode 220 and the second auxiliary electrode 240s. In a sensing mode, the sensor driver 200C may receive the induced current flowing from the second auxiliary electrode 240s to the second electrode 220 through the second coupling capacitors Cop21, Ccp22, Ccp23, and Ccp24. In other words, each of the second coupling capacitors Ccp21, Ccp22, Ccp23, and Ccp24 may play the role of supplying current. Each of the second coupling capacitors Ccp21, Ccp22, Ccp23, and Ccp24 may indicate the sensitivity of the pen PN.

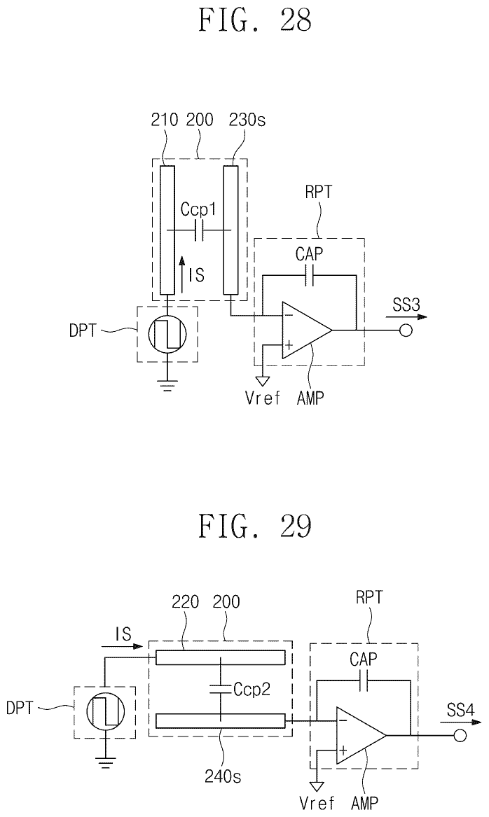

FIG. 28 is a diagram schematically illustrating a sensor layer and a sensor driver, according to some embodiments of the present disclosure. In the description of FIG. 28, the same reference numerals are assigned to the same components described with reference to FIG. 22, and thus the descriptions thereof are omitted.

Referring to FIGS. 5, 23, and 28, operation S220 of measuring the sensitivity of the pen PN may include an operation of measuring the first coupling capacitor Ccp1 and an operation of measuring the second coupling capacitor Ccp2.

In the operation of measuring the first coupling capacitor Ccp1, the driver DPT may be electrically connected to the plurality of first electrodes 210, and the sensing unit RPT may be electrically connected to the plurality of first auxiliary electrodes 230s.

The driver DPT may transmit the test signal IS to at least one of the plurality of first electrodes 210.

The sensing unit RPT may receive a third sensing signal SS3 for the test signal IS from each of the plurality of first auxiliary electrodes 230s. The third sensing signal SS3 may correspond to the capacitance of the first coupling capacitor Ccp1 formed between the plurality of first electrodes 210 and the first auxiliary electrode 230s.

The third sensing signal SS3 may be provided to the analysis unit 200C1. The analysis unit 200C1 may test the sensitivity of the pen PN based on the third sensing signal SS3. However, this is an example. For example, a method of measuring the first coupling capacitor Ccp1 according to some embodiments of the present disclosure is not limited thereto. For example, the driver DPT may transmit the test signal IS to the plurality of first auxiliary electrodes 230s, and may receive the third sensing signal SS3 for the test signal IS from each of the plurality of first electrodes 210.

FIG. 29 is a diagram schematically illustrating a sensor layer and a sensor driver, according to some embodiments of the present disclosure. In the description of FIG. 29, the same reference numerals are assigned to the same components described with reference to FIG. 22, and thus the descriptions thereof are omitted.

Referring to FIGS. 5, 23, and 29, in an operation of measuring the second coupling capacitor Ccp2, the driver DPT may be electrically connected to the plurality of second electrodes 220, and the sensing unit RPT may be electrically connected to the plurality of second auxiliary electrodes 240s.

The driver DPT may transmit the test signal IS to at least one of the plurality of second electrodes 220.

The sensing unit RPT may receive a fourth sensing signal SS4 for the test signal IS from each of the plurality of second auxiliary electrodes 240s. The fourth sensing signal SS4 may correspond to the capacitance of the second coupling capacitor Ccp2 formed between the plurality of second electrodes 220 and the second auxiliary electrode 240s.

The fourth sensing signal SS4 may be provided to the analysis unit 200C1. The analysis unit 200C1 may test the sensitivity of the pen PN based on the fourth sensing signal SS4. However, this is an example. For example, a method of measuring the second coupling capacitor Ccp2 according to some embodiments of the present disclosure is not limited thereto. For example, the driver DPT may transmit the test signal IS to the plurality of second auxiliary electrodes 240s, and may receive the fourth sensing signal SS4 for the test signal IS from each of the plurality of second electrodes 220.

According to some embodiments of the present disclosure, the sensor driver 200C may test the sensitivity of the pen PN without inputting a signal by using the pen PN by measuring the first coupling capacitor Ccp1 and the second coupling capacitor Ccp2. In other words, the sensitivity for the second input 3000 may be tested without the pen PN. Accordingly, the process of testing the electronic device 1000 may be relatively simplified and the test time may be relatively shortened.

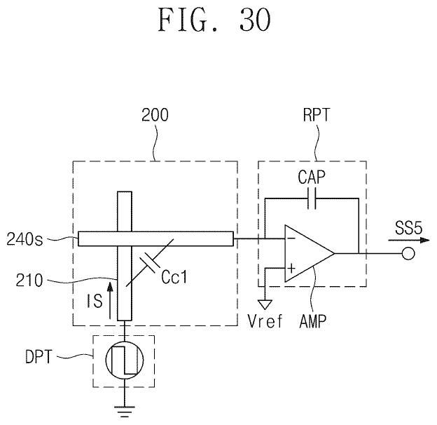

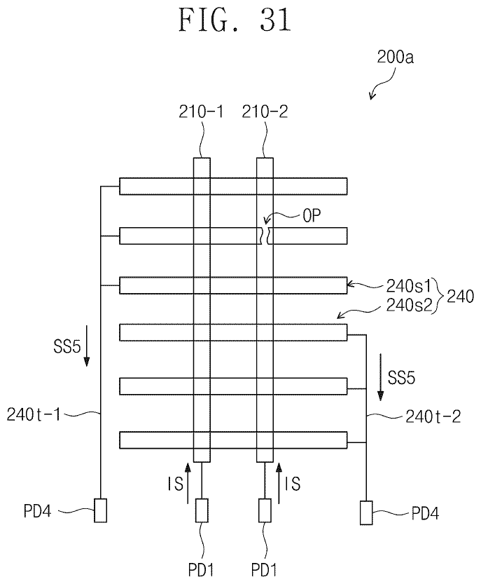

FIG. 30 is a diagram schematically illustrating a sensor layer and a sensor driver, according to some embodiments of the present disclosure. FIG. 31 is a diagram illustrating a sensor layer, in which an open occurs in a second auxiliary electrode, according to some embodiments of the present disclosure. In the description of FIG. 30, the same reference numerals are assigned to the same components described with reference to FIG. 22, and thus the descriptions thereof are omitted. In the description of FIG. 31, the same reference numerals are assigned to the same components described with reference to FIG. 8, and thus the descriptions thereof are omitted.

Referring to FIGS. 5, 23, 30, and 31, operation S230 of supplementarily testing the pen electrodes 230 and 240 may include an operation of testing the second auxiliary electrodes 240s and an operation of testing the first auxiliary electrodes 230s.

In the operation of testing the second auxiliary electrodes 240s, the driver DPT may be electrically connected to the plurality of first electrodes 210, and the sensing unit RPT may be electrically connected to the plurality of second auxiliary electrodes 240s.

The driver DPT may transmit the test signal IS to at least one of the plurality of first electrodes 210.

The sensing unit RPT may receive a fifth sensing signal SS5 for the test signal IS from each of the plurality of second auxiliary electrodes 240s. The fifth sensing signal SS5 may correspond to the capacitance of a third coupling capacitor Cc1 formed between the plurality of first electrodes 210 and the second auxiliary electrode 240s.

The fifth sensing signal SS5 may be provided to the analysis unit 200C1. The analysis unit 200C1 may test open or short defects of the plurality of second auxiliary electrodes 240s based on the fifth sensing signal SS5.

However, this is an example. For example, a method of measuring the third coupling capacitor Cc1 according to some embodiments of the present disclosure is not limited thereto. For example, the driver DPT may transmit the test signal IS to the plurality of second auxiliary electrodes 240s, and may receive the fifth sensing signal SS5 for the test signal IS from each of the plurality of first electrodes 210.

An open OP may occur in one of the plurality of second auxiliary electrodes 240s in a sensor layer 200a according to some embodiments of the present disclosure.

The sensor driver 200C may be electrically connected to the plurality of first pads PD1 and the plurality of fourth pads PD4.

The sensor driver 200C may perform a scan operation by transmitting the test signal IS to each of the plurality of first electrodes 210.

The sensor driver 200C may transmit the test signal IS to one electrode 210-1 of the plurality of first electrodes 210. The sensing unit RPT may receive the fifth sensing signal SS5 for the test signal IS from the second auxiliary electrode 240s1 and may receive the fifth sensing signal SS5 for the test signal IS from the second auxiliary electrode 240s2. The analysis unit 200C1 may receive a first test value of the fifth sensing signal SS5. The first test value may include the capacitance of the third coupling capacitor Cc1.

The sensor driver 200C may transmit the test signal IS to another electrode 210-2 of the plurality of first electrodes 210. The sensing unit RPT may receive the fifth sensing signal SS5 for the test signal IS from the second auxiliary electrode 240s1 and may receive the fifth sensing signal SS5 for the test signal IS from the second auxiliary electrode 240s2. The analysis unit 200C1 may receive a second test value of the fifth sensing signal SS5. The second test value may include the capacitance of the third coupling capacitor Cc1.

When the first test value is greater than the second test value, the analysis unit 200C1 may determine that the open OP occurs in an area, which overlaps the other electrode 210-2 of the plurality of first electrodes 210, in the plurality of second auxiliary electrodes 240s1.

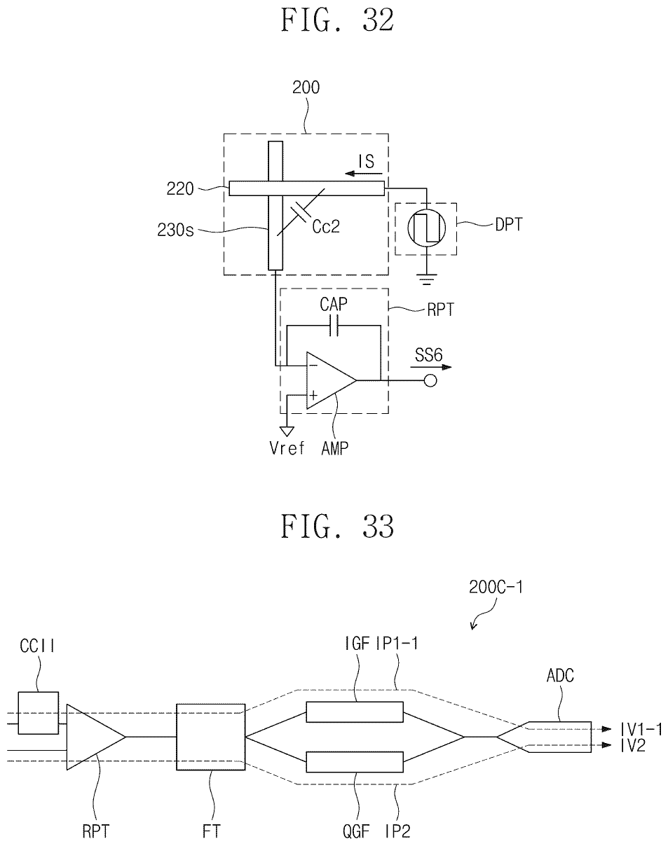

FIG. 32 is a diagram schematically illustrating a sensor layer and a sensor driver, according to some embodiments of the present disclosure. In the description of FIG. 32, the same reference numerals are assigned to the same components described with reference to FIG. 22, and thus the descriptions thereof are omitted.

Referring to FIGS. 5, 23, and 32, in an operation of testing the first auxiliary electrodes 230s, the driver DPT may be electrically connected to the plurality of second electrodes 220, and the sensing unit RPT may be electrically connected to the plurality of first auxiliary electrodes 230s.

The driver DPT may transmit the test signal IS to at least one of the plurality of second electrodes 220.

The sensing unit RPT may receive a sixth sensing signal SS6 for the test signal IS from each of the plurality of first auxiliary electrodes 230s. The sixth sensing signal SS6 may correspond to the capacitance of a fourth coupling capacitor Cc2 formed between the plurality of second electrodes 220 and the plurality of first auxiliary electrode 230s.

The sixth sensing signal SS6 may be provided to the analysis unit 200C1. The analysis unit 200C1 may test open or short defects of the plurality of first auxiliary electrodes 230s based on the sixth sensing signal SS6.

However, this is an example. For example, a method of measuring the fourth coupling capacitor Cc2 according to some embodiments of the present disclosure is not limited thereto. For example, the driver DPT may transmit the test signal IS to the plurality of first auxiliary electrodes 230s, and may receive the sixth sensing signal SS6 for the test signal IS from each of the plurality of second electrodes 220.

In the sensor layer 200 according to some embodiments of the present disclosure, at least two of the plurality of first auxiliary electrodes 230s may be connected to each other, and at least two of the plurality of second auxiliary electrodes 240s may be connected to each other. In an operation of testing short states of the pen electrodes 230 and 240 and an operation of testing open states of the pen electrodes 230 and 240, it may be difficult to accurately measure the short or open state at some locations compared to an operation of testing short states of the touch electrodes 210 and 220 and an operation of testing open states of the touch electrodes 210 and 220. However, according to some embodiments of the present disclosure, operation S200 (see FIG. 19) of testing the sensor layer 200 may include operation S230 of supplementarily testing the pen electrodes 230 and 240. Through operation S230 of supplementarily testing the pen electrodes 230 and 240, the fifth sensing signal SS5 (see FIG. 30) and the sixth sensing signal SS6 may be received. The analysis unit 200C1 may determine the short or open state of each of the plurality of first auxiliary electrodes 230s and the plurality of second auxiliary electrodes 240s based on the fifth sensing signal SS5 (see FIG. 30) and the sixth sensing signal SS6. The analysis unit 200C1 may determine the short or open state of each of the plurality of first auxiliary electrodes 230s and the plurality of second auxiliary electrodes 240s, by combining the test results derived from operation S210 of testing the short or open state of the sensor layer 200 and operation S230 of supplementarily testing the pen electrodes 230 and 240. Accordingly, a method for testing the electronic device 1000 with relatively improved reliability may be provided.

FIG. 33 is a block diagram illustrating a sensor driver, according to some embodiments of the present disclosure. In the description of FIG. 33, the same reference numerals are assigned to the same components described with reference to FIG. 20, and thus the descriptions thereof are omitted.

Referring to FIGS. 5, 19, 22, and 33, a sensor driver 200C-1 may include a current conveyor CCII, the sensing unit RPT, the filter unit FT, the in-phase filter IGF, the quadrature phase filter QGF, and the analog-to-digital converter ADC.

The current conveyor CCII may be connected between the sensing unit RPT and the sensor layer 200. The current conveyor CCII may be a second-generation current controlled conveyor. The current conveyor CCII may separate the load applied to the sensor layer 200 and the load applied to the sensor driver 200C. For this reason, the bandwidth of the signal input to the sensing unit RPT may be relatively improved.

The sensing signal for the test signal IS received from the sensor layer 200 in operation S100 of testing the sensor driver 200C-1 may be output as a third test value IV1-1 through a third test path IP1-1.

The third test path IP1-1 may be a path for passing through the current conveyor CCII, the sensing unit RPT, the in-phase filter IGF, and the analog-to-digital converter ADC.

The second test path IP2 may not pass through the current conveyor CCII.

The third test value IV1-1 may be provided to the analysis unit 200C1. The analysis unit 200C1 may determine whether the third test value IV1-1 is within a normal range.

The analysis unit 200C1 may compare the third test value IV1-1 and the second test value IV2.

When the second test value IV2 is within the normal range and the third test value IV1-1 is outside the normal range, the analysis unit 200C1 may determine that the current conveyor CCII is abnormal.

When the third test value IV1-1 is within the normal range, and the second test value IV2 is outside the normal range, the analysis unit 200C1 may determine that the quadrature phase filter QGF is abnormal.

According to some embodiments of the present disclosure, it may be possible to relatively easily determine which component of the sensor driver 200C is abnormal, by comparing the second test value IV2 and the third test value IV1-1. Accordingly, a process of testing the sensor driver 200C may be relatively simplified, and the test time may be relatively shortened.

Although some embodiments of the present disclosure has been described for illustrative purposes, those skilled in the art will appreciate that various modifications, and substitutions are possible, without departing from the scope and spirit of the present disclosure as disclosed in the accompanying claims. Accordingly, the technical scope of embodiments according to the present disclosure are not limited to the detailed description of this specification, but should be defined by the claims.

As described above, it may be possible to determine whether a sinusoidal signal is capable of being interpreted, without inputting a signal by using a pen through an operation of testing a quadrature phase filter. In other words, it may be possible to relatively easily determine whether a sensor driver is capable of interpreting a second input without a pen. Accordingly, a process of testing the sensor driver may be relatively simplified, and the test time may be relatively shortened.

Moreover, as described above, the sensor driver may test the sensitivity of the pen without inputting a signal by using the pen by measuring a first coupling capacitor and a second coupling capacitor. That is, it may be possible to test the sensitivity of an input by the pen without the pen. Accordingly, the process of testing an electronic device may be relatively simplified and the test time may be shortened.

While aspects of some embodiments of the present disclosure have been described with reference to some embodiments thereof, it will be apparent to those of ordinary skill in the art that various changes and modifications may be made thereto without departing from the spirit and scope of embodiments according to the present disclosure as set forth in the following claims, and their equivalents.

What is claimed is:

1. An electronic device testing method, the method comprising:
providing an electronic device including a sensor layer and a sensor driver driving the sensor layer; and
testing the electronic device as the sensor driver transmits a test signal to the sensor layer,
wherein the sensor layer includes:
a plurality of first electrodes arranged in a first direction and extending in a second direction intersecting the first direction; and
a plurality of second electrodes arranged in the second direction and extending in the first direction,
wherein the sensor driver includes an in-phase filter and a quadrature phase filter,
wherein the testing of the electronic device includes:
testing the sensor driver,
wherein the testing of the sensor driver includes:
transmitting the test signal to the plurality of first electrodes and receiving a sensing signal for the test signal through the plurality of second electrodes;
outputting a first test value obtained as the sensing signal passes through the in-phase filter;
outputting a second test value obtained as the sensing signal passes through the quadrature phase filter; and
comparing the first test value and the second test value.

2. The method of claim 1, wherein the comparing of the first test value and the second test value includes:
determining that the quadrature phase filter is operating normally, based on the first test value and the second test value being within a normal range and are similar to each other; and
determining that the quadrature phase filter is abnormal, based on the first test value being within the normal range and the second test value being outside the normal range.

3. The method of claim 1, wherein the receiving of the sensing signal includes:
measuring mutual capacitance between the plurality of first electrodes and the plurality of second electrodes.

4. The method of claim 2, wherein the sensor driver further includes a current conveyor circuit, and
wherein testing the sensor driver further includes:
receiving a third test value obtained as the sensing signal passes through the current conveyor circuit and the in-phase filter; and
comparing the third test value and the second test value.

5. The method of claim 4, wherein the comparing of the third test value and the second test value includes:
determining that the current conveyor circuit is abnormal, based on the second test value being within the normal range and the third test value being outside the normal range.

6. The method of claim 1, wherein the sensor layer further includes:
a plurality of first auxiliary electrodes arranged in the first direction, extending in the second direction, and overlapping the plurality of first electrodes; and
a plurality of second auxiliary electrodes arranged in the second direction, extending in the first direction, and overlapping the plurality of second electrodes.

7. The method of claim 6, wherein the testing of the electronic device further includes:
testing the sensor layer, and
wherein testing the sensor layer includes:
testing a short state of the sensor layer; and
testing an open state of the sensor layer.

8. The method of claim 7, wherein testing the short state of the sensor layer includes:
transmitting the test signal to the plurality of first electrodes and receiving a 1-1st sensing signal for the test signal through the plurality of second electrodes;
determining short states of the plurality of first electrodes and the plurality of second electrodes based on the 1-1st sensing signal;
transmitting the test signal to the plurality of first auxiliary electrodes and receiving a 2-1st sensing signal for the test signal through the plurality of second auxiliary electrodes; and
determining short states of the plurality of first auxiliary electrodes and the plurality of second auxiliary electrodes based on the 2-1st sensing signal.

9. The method of claim 7, wherein testing the open state of the sensor layer includes:
transmitting the test signal to the plurality of first electrodes and receiving a 1-2nd sensing signal for the test signal through the plurality of second electrodes;
determining open states of the plurality of first electrodes and the plurality of second electrodes based on the 1-2nd sensing signal;
transmitting the test signal to the plurality of first auxiliary electrodes and receiving a 2-2nd sensing signal for the test signal through the plurality of second auxiliary electrodes; and
determining open states of the plurality of first auxiliary electrodes and the plurality of second auxiliary electrodes based on the 2-2nd sensing signal.

10. The method of claim 7, wherein testing the sensor layer further includes:
measuring sensitivity of a pen; and
supplementarily testing the plurality of first auxiliary electrodes and the plurality of second auxiliary electrodes.

11. The method of claim 10, wherein measuring the sensitivity of the pen includes:
transmitting the test signal to the plurality of first electrodes and receiving a third sensing signal for the test signal through the plurality of first auxiliary electrodes;
transmitting the test signal to the plurality of second electrodes and receiving a fourth sensing signal for the test signal through the plurality of second auxiliary electrodes; and
testing the sensitivity of the pen based on the third sensing signal and the fourth sensing signal.

12. The method of claim 10, wherein the supplementarily testing of the plurality of first auxiliary electrodes and the plurality of second auxiliary electrodes includes:
transmitting the test signal to the plurality of first electrodes and receiving a fifth sensing signal for the test signal through the plurality of second auxiliary electrodes; and
testing the plurality of second auxiliary electrodes based on the fifth sensing signal.

13. The method of claim 10, wherein the supplementarily testing of the plurality of first auxiliary electrodes and the plurality of second auxiliary electrodes further includes:
transmitting the test signal to the plurality of second electrodes and receiving a sixth sensing signal for the test signal through the plurality of first auxiliary electrodes; and
testing the plurality of first auxiliary electrodes based on the sixth sensing signal.

14. The method of claim 12, wherein the testing of the plurality of second auxiliary electrodes includes:
based on a test value of the fifth sensing signal for the test signal transmitted to one of the plurality of first electrodes being greater than a test value of the fifth sensing signal for the test signal transmitted to another one adjacent to the one of the plurality of first electrodes, determining that an open occurs in an area, which overlaps the another one of the plurality of first electrodes, in the plurality of second auxiliary electrodes.

15. A sensor driver configured to drive a sensor layer including a plurality of first electrodes and a plurality of second electrodes respectively intersecting the plurality of first electrodes in an insulation method, the sensor driver comprising:
a driver configured to output a test signal to the sensor layer;
a receiving unit electrically connected to the sensor layer;
an in-phase filter electrically connected to the receiving unit;
a quadrature phase filter electrically connected to the receiving unit; and
an analysis unit electrically connected to the in-phase filter and the quadrature phase filter,
wherein the driver is configured to:
transmit the test signal to the plurality of first electrodes,
wherein the receiving unit is configured to:
receive a first sensing signal for the test signal from the plurality of second electrodes,
wherein the first sensing signal passes through the in-phase filter and is output as a first test value, and
wherein the first sensing signal passes through the quadrature phase filter and is output as a second test value.

16. The sensor driver of claim 15, wherein the first sensing signal is a mutual capacitance between the plurality of first electrodes and the plurality of second electrodes, and
wherein the analysis unit tests the quadrature phase filter by comparing the first test value and the second test value.

17. The sensor driver of claim 15, further comprising:
a filter unit connected to the receiving unit; and
an analog-to-digital converter connected between the analysis unit and the in-phase filter or the quadrature phase filter.

18. The sensor driver of claim 15, wherein the sensor layer further includes:
a plurality of first auxiliary electrodes arranged in a first direction, extending in a second direction intersecting the first direction, and overlapping the plurality of first electrodes; and
a plurality of second auxiliary electrodes arranged in the second direction, extending in the first direction, and overlapping the plurality of second electrodes, and
wherein the driver is configured to transmit the test signal to the plurality of first auxiliary electrodes, and the receiving unit is configured to output a second sensing signal through the plurality of second auxiliary electrodes.

19. The sensor driver of claim 18, wherein the driver is configured to transmit the test signal to the plurality of first electrodes, and the receiving unit is configured to output a third sensing signal through the plurality of first auxiliary electrodes, and
wherein the driver is configured to transmit the test signal to the plurality of second electrodes, and the receiving unit is configured to output a fourth sensing signal through the plurality of second auxiliary electrodes.

20. The sensor driver of claim 18, wherein the driver is configured to transmit the test signal to the plurality of first electrodes and to output a fifth sensing signal for the test signal through the plurality of first auxiliary electrodes,
wherein the driver is configured to transmit the test signal to the plurality of second electrodes and to output a sixth sensing signal for the test signal through the plurality of second auxiliary electrodes.

21. An electronic device comprising:
a display layer;
a sensor layer on the display layer; and
a sensor driver configured to drive the sensor layer,
wherein the sensor layer includes:
a plurality of first electrodes arranged in a first direction and extending in a second direction intersecting the first direction; and
a plurality of second electrodes arranged in the second direction and extending in the first direction,
wherein the sensor driver includes:
a driver configured to output a test signal to the sensor layer;
a receiving unit electrically connected to the sensor layer;
an in-phase filter electrically connected to the receiving unit; and
a quadrature phase filter electrically connected to the receiving unit,
wherein the driver is configured to:
transmit the test signal to the plurality of first electrodes,
wherein the receiving unit is configured to:
receive a sensing signal for the test signal from the plurality of second electrodes,
wherein the sensing signal passes through the in-phase filter and is output as a first test value, and
wherein the sensing signal passes through the quadrature phase filter and is output as a second test value.

22. The electronic device of claim 21, wherein the first sensing signal is mutual capacitance between the plurality of first electrodes and the plurality of second electrodes.

23. The electronic device of claim 21, wherein the sensor layer further includes:
a plurality of first auxiliary electrodes arranged in the first direction, extending in the second direction, and overlapping the plurality of first electrodes; and
a plurality of second auxiliary electrodes arranged in the second direction, extending in the first direction, and overlapping the plurality of second electrodes, and
wherein the driver is configured to transmit the test signal to the plurality of first auxiliary electrodes, and the receiving unit is configured to output a second sensing signal through the plurality of second auxiliary electrodes.

24. The electronic device of claim 23, wherein the driver is configured to transmit the test signal to the plurality of first electrodes, and the receiving unit is configured to output a third sensing signal through the plurality of first auxiliary electrodes, and
wherein the driver is configured to transmit the test signal to the plurality of second electrodes, and the receiving unit is configured to output a fourth sensing signal through the plurality of second auxiliary electrodes.

25. The electronic device of claim 23, wherein the driver is configured to transmit the test signal to the plurality of first electrodes and to output a fifth sensing signal for the test signal through the plurality of first auxiliary electrodes, and
wherein the driver is configured to transmit the test signal to the plurality of second electrodes and to output a sixth sensing signal for the test signal through the plurality of second auxiliary electrodes.

26. The electronic device of claim 21, wherein the sensor driver further includes:
a filter unit connected to the receiving unit; and
an analog-to-digital converter electrically connected to the in-phase filter and the quadrature phase filter.

27. The electronic device of claim 26, wherein the sensor driver further includes a current conveyor circuit electrically connected to the in-phase filter.
